(19) United States
(12) Patent Application Publication
(10) Pub. No.: US 2008/0271784 A1
(43) Pub. Date: Nov. 6, 2008

(54) ELECTRO-OPTIC PRISM SYSTEMS

(75) Inventors: Dwight P. Duston, Laguna Niguel, CA (US); Joshua N. Haddock, Roanoke, VA (US); William Kokonaski, Gig Harbor, WA (US); Ronald D. Blum, Roanoke, VA (US)

Correspondence Address: FISH & RICHARDSON P.C., P.O BOX 1022, Minneapolis, MN, 55440-1022, US

(73) Assignee: SolBeam, Inc., Laguna Niguel, CA (US)

(21) Appl. No.: 11/615,798

(22) Filed: Dec. 22, 2006

Related U.S. Application Data
(60) Provisional application No. 60/752,386, filed on Dec. 22, 2005.
(60) Provisional application No. 60/778,918, filed on Mar. 6, 2006.
(60) Provisional application No. 60/797,691, filed on May 5, 2006.

(51) Int. Cl. H01L 31/00

(52) U.S. Cl. 136/259

(57) ABSTRACT

Techniques and assemblies for steering light rays are described. An electro-optic prism configured to provide controllable steering of solar rays includes a first electrode including multiple substantially parallel linear electrodes positioned on a first substrate and a reference electrode positioned on a second substrate. An electro-optic material is positioned between the first electrode and the reference electrode. In one implementation, a wavelength selective filter is in optical communication with the electro-optic prism. The wavelength selective filter is configured to substantially eliminate selected wavelengths from solar rays before the solar rays are received by the electro-optic prism. In another implementation, a chemical compound is configured in the assembly to convert ultra-violet photons included in the solar rays into visible photons.

### CROSS REFERENCE TO RELATED APPLICATIONS

This application claims priority to pending: U.S. Provisional Application Ser. No. 60/752,386, entitled “Prismatic Alignment of Sunlight for Solar Concentrators,” filed on Dec. 22, 2005; U.S. Provisional Application Ser. No. 60/778,918, entitled “Dynamic Steering of Light Rays by Electro-Optic and Opto-Mechanic Means,” filed on Mar. 6, 2006; and U.S. Provisional Application Ser. No. 60/797,691, entitled “Dynamic Steering of Light Rays by Electro-Optic and Opto-Mechanic Means,” filed on May 5, 2006; the entire contents of which above three provisional applications are hereby incorporated by reference.

### TECHNICAL FIELD

This invention generally relates to techniques and assemblies for steering light rays.

### BACKGROUND

Focusing light rays emanating from either a natural or an artificial source can be useful for various different applications. For example, steering solar rays to direct them toward a photovoltaic cell or to direct them toward a light focusing element, which then focuses the solar rays on a photovoltaic cell, can be useful in solar energy collection applications. Generally, a photovoltaic cell (or other device for capturing solar energy) is a device that captures solar radiation and converts the radiation into electric potential or current. A conventional photovoltaic cell is typically configured as a flat substrate supporting an absorbing layer, which captures impinging solar radiation, and electrodes, or conducting layers, which serve to transport electrical charges created within the cell.

A solar concentrator is a light focusing element that can be employed to multiply the amount of sunlight, i.e., the solar flux, impinging on a photovoltaic cell. A solar energy collection assembly, or array, can be mounted on a moveable platform, in an attempt to keep the absorbing layer directed approximately normal to the solar rays as the sun tracks the sky over the course of a day. If a light focusing element, such as a lens or curved mirror, is included in the solar energy collection assembly to focus the solar rays toward the photovoltaic cells, the assembly's position can be adjusted in an attempt to keep the receiving surface of the light focusing element directed approximately normal to the solar rays. The platform can be moved manually or automatically by mechanical means, and various techniques can be employed to track the sun.

In general, light rays refract upon passing through a triangular prism at a fixed angle that depends on the prism apex angle, wavelength of light, the refractive index of the prism material, and the incident angle of the light rays, assuming the light rays are not totally internally reflected inside the prism. A prism used together with a layer of liquid crystal positioned between two contiguous electrodes, such as that described in U.S. Pat. No. 6,958,868, can refract light of a given wavelength at many different angles, because the refractive index of the liquid crystal layer can be varied by varying the strength of electrical field across the layer. The refractive angle of the light rays, as they pass through the prism assembly, can therefore be controlled within some limitations by varying the applied electric field, thereby steering the light rays within some angular range. A solar energy collection assembly employing such a prism assembly to steer solar rays toward a light focusing element is described in U.S. Pat. No. 6,958,868.

### SUMMARY

This invention relates to techniques and assemblies for steering light rays. In general, in one aspect, the invention features an assembly including an electro-optic prism configured to provide controllable steering of solar rays. The electro-optic prism includes a first electrode including multiple substantially parallel linear electrodes positioned on a first substrate and a reference electrode positioned on a second substrate. An electro-optic material is positioned between the first electrode and the reference electrode such that, when separately controllable voltages are provided to at least some of the linear electrodes, a gradient electric field is provided within the electro-optic material to cause the electro-optic material to have a refractive index gradient and wherein the refractive index gradient can be controlled by varying the magnitude of the separately controllable voltages provided to at least some of the linear electrodes. A wavelength selective filter is in optical communication with the electro-optic prism. The wavelength selective filter is configured to substantially eliminate selected wavelengths from solar rays before the solar rays are received by the electro-optic prism.

Implementations of the invention can include one or more of the following features. The wavelength selective filter can be one that substantially blocks infrared radiation, where infrared radiation includes wavelengths greater than approximately 1800 nanometers. By way of example, the wavelength selective filter can be a dichroic mirror, an interference filter, a diffraction grating or a cut-off filter. The assembly can further include a light focusing element. The light focusing element can be arranged in optical communication with the dynamic variable-power electro-optic prism and positioned to receive and concentrate the solar rays after having passed through the dynamic variable-power electro-optic prism. The assembly can further include a photovoltaic device in optical communication with the light focusing element, where the light focusing element concentrates the light rays toward the photovoltaic device.

In general, in another aspect, the invention features an assembly including an electro-optic prism configured to provide controllable steering of solar rays. The electro-optic prism includes a first electrode including multiple substantially parallel linear electrodes positioned on a first substrate and a reference electrode positioned on a second substrate. An electro-optic material is positioned between the first electrode and the reference electrode such that, when separately controllable voltages are provided to at least some of the linear electrodes, a gradient electric field is provided within the electro-optic material to cause the electro-optic material to have a refractive index gradient. The refractive index gradient can be controlled by varying the magnitude of the separately controllable voltages provided to at least some of the linear electrodes. A chemical compound is configured in the assembly to convert ultra-violet photons included in the solar rays into visible photons.

Implementations of the invention can include one or more of the following features. The chemical compound can be included within the electro-optic material of the electro-optic prism. Alternatively, the chemical compound can be a material in optical communication with the electro-optic prism. By way of example, the chemical compound can be an organic dye compound, an inorganic phosphor, e.g., a semiconductor material that can exhibit quantum confinement.

The assembly can further include a light focusing element. The light focusing element can be arranged in optical communication with the electro-optic prism and positioned to receive and concentrate the solar rays after having passed through the electro-optic prism. The assembly can further include a photovoltaic device in optical communication with the light focusing element, where the light focusing element concentrates the light rays toward the photovoltaic device.

In general, in another aspect, the invention features an assembly including an electro-optic prism configured to provide controllable steering of solar rays. The electro-optic prism includes a first electrode including multiple substantially parallel linear electrodes positioned on a first substrate and a reference electrode positioned on a second substrate. An electro-optic material is positioned between the first electrode and the reference electrode. A wavelength selective filter is in optical communication with the electro-optic prism. The wavelength selective filter is configured to substantially eliminate selected wavelengths from solar rays before the solar rays are received by the electro-optic prism.

In general, in another aspect, the invention features an assembly including an electro-optic prism configured to provide controllable steering of solar rays. The electro-optic prism includes a first electrode including multiple substantially parallel linear electrodes positioned on a first substrate and a reference electrode positioned on a second substrate. An electro-optic material is positioned between the first electrode and the reference electrode A chemical compound is configured in the assembly to convert ultra-violet photons included in the solar rays into visible photons.

Implementations of the invention can include one or more of the following.

Implementations of the invention can realize one or more of the following advantages. The light rays can be steered in one or more directions with an assembly that does not require physical adjustment to account for a moving light source. When applied in the context of a solar energy collection assembly, the assembly can be configured to steer light rays to account for one or both of the sun's east-west and north-south movement overhead, without requiring the assembly to physically move. The solar energy collection assembly can thereby exhibit improved efficiency, reduced size, and a less complicated mounting structure.

Conventional solar tracking systems can be large, expensive, invite mechanical failure, and be unsightly, potentially deterring people who might otherwise choose to employ photovoltaic technology as a source of electric power. The solar energy collection assemblies described herein provide reduced mechanical aspects, decreased cost, and significantly reduced visual presence.

A light wave impinging with some oblique angle upon a layer of birefringent material, such as liquid crystal, can be steered into a different angle if an applied electric potential creates a gradient in the index of refraction (index gradient) in the birefringent material. This is the electro-optic analog of an optical prism; however, unlike a physical prism, the electric-optic prism can be tuned to refract light at an arbitrary angle by varying the electric potential and, hence, the index gradient.

A combination of two or more prisms, each having a different alignment and/or different electro-optic properties, can be used to achieve both coarse and fine solar ray steering. Combining a physically adjustable prism with a non-moving electro-optic prism can provide improved solar ray steering in either one or two directions. Solar steering can be improved by providing a solar energy collection assembly including an elongated photovoltaic element extending in at least one direction, e.g., the east-west direction, and including one or more electro-optic prisms configured to provide solar ray steering in a perpendicular, e.g., north-south direction.

Birefringent nematic liquid crystals require two layers of orthogonally-aligned electro-optic material to act upon both polarizations of unpolarized light, such as sunlight. The number of electro-optic layers required to steer unpolarized light, e.g., solar rays, can be reduced by using cholesteric liquid crystal as the electro-optic material.

Lensing, a deleterious effect caused by variations in an electric field within an electro-optic prism, can be reduced or eliminated using implementations described herein. For example, use of a variable resistance electrode can provide a substantially homogeneous electric field, thereby reducing or eliminating lensing effects.

Light rays incident on a prism can be steered by altering a property of the prism, other than the refractive index. Altering the apex angle also alters the refraction angle, thereby allowing for controlled light steering.

Potentially damaging radiation can be substantially reduced from solar rays incident on a solar energy collection assembly through use of a filter.

Some spectral components of solar radiation that reach a photovoltaic device can be outside the absorptive capabilities of light-absorbing material within the device. These photons can be absorbed by chromophores within the prism material, which then emit photons at a different wavelength, and can be absorbed by the photovoltaic device. For example, ultra-violet photons included in solar rays can be converted into visible photons absorbable by a photovoltaic cell.

A particular advantage of the light steering assemblies described herein is that they can be used to steer solar light rays in a wider range of incidence angles than conventional steering optics, such as isosceles or equilateral prisms. These conventional components suffer from reflection losses, including total internal reflection, when light incident upon a receiving face of the prism enters at oblique angles. The loss can be a significant factor in photovoltaic systems. The implementations described herein can overcome this problem by using patterned electrodes to create a refractive index gradient within a substantially flat electro-optic material. The generated index gradient within the material is the analog of a traditional optical prism element, e.g., a glass prism, in that light bends as it travels through the material at an angle controlled by the magnitude of the gradient. A distinct advantage of the methods and articles described herein is that the receiving surface of the electro-optic prism does not need to be adjusted to compensate for oblique incidence angles, as described below.

Each electrode within the electro-optic material can receive an independently-controlled voltage, and an index gradient can be created within the electro-optic material in a preferred direction. The electro-optic prism can therefore refract incident light rays for many incidence angles (along a particular planar axis) by controlling the voltage applied to the electrodes. This is particularly useful for receiving light rays from a moving source, such as from the sun. As the sun rises in the east, the index gradient can be set, by virtue of the applied electric fields, such that incident light rays will be steered toward a light focusing element and/or photovoltaic surface such that the rays enter perpendicular to the light focusing element surface. As the sun moves toward its zenith (i.e., solar noon) the index gradient can be changed to compensate for the movement. When the sun's position is such that it substantially normal to the flat surface of the electro-optic prism (i.e., solar noon), the sun's rays may pass directly through the material by simply turning off the applied electric field, thereby removing the index gradient. Upon westerly movement of the sun, the index gradient direction may be re-applied, reversed from that when the sun was rising from the east. For example, referring to FIGS. 2B-D, when the sun rises in the east and continues to its zenith, the voltages applied to electrodes 210a through 210f may increase from 210a to 210f. This particular arrangement may properly refract light rays to a receiving photovoltaic surface during this time period. When the sun continues from its zenith towards the west, the voltages applied to the electrodes may now increase from 210f to 210a, the reverse of that for the previous time period. This has the effect of reversing direction of the index gradient, and therefore the acceptable incidence angle, and allows solar rays to be steered effectively during the entire course of a day.

The details of one or more implementations of the invention are set forth in the accompanying drawings and the description below. Other features, objects, and advantages of the invention will be apparent from the description and drawings, and from the claims.

### DESCRIPTION OF DRAWINGS

The foregoing summary as well as the following detailed description of the preferred implementation of the invention will be better understood when read in conjunction with the appended drawings. It should be understood, however, that the invention is not limited to the precise arrangements and instrumentalities shown herein. The components in the drawings are not necessarily to scale, emphasis instead being placed upon clearly illustrating the principles of the present invention.

FIG. 1 shows a schematic representation of a simplified solar energy collection assembly.

FIGS. 2A-E show schematic representations of solar energy collection assemblies including electro-optic prisms.

FIG. 3 shows a cross-sectional view of a schematic representation of an electro-optic prism/light focusing element assembly.

FIG. 4 shows a cross-sectional view of a schematic representation of an alternative implementation of an electro-optic prism/light focusing element assembly.

FIG. 5 shows a cross-sectional view of a schematic representation of an alternative implementation of an electro-optic prism/light focusing element assembly.

FIG. 6 shows a cross-sectional view of a schematic representation of a prism/light focusing element assembly.

FIG. 7 shows a cross-sectional view of a schematic representation of a dynamic fixed-power electro-optic prism.

FIG. 8 shows a cross-sectional view of a schematic representation of an alternative implementation of a prism/light focusing element assembly.

FIGS. 9A-B show a schematic representation of a light directing assembly including an adjuster and an electro-optic prism/light focusing element assembly.

FIG. 10 shows a schematic representation of an elongated solar collecting system positioned on a roof.

FIG. 11 shows a schematic representation of an electro-optic prism/light focusing element assembly.

FIGS. 12A-B show cross-sectional views of a schematic representation of an implementation of a dynamic electro-optic prism.

FIG. 13 shows a cross-sectional view of a schematic representation of an electro-optic prism exhibiting a lensing effect.

FIG. 14 shows a cross-sectional view of a schematic representation of a dynamic electro-optic prism including discrete patterned electrodes.

FIG. 15 shows a cross-sectional view of a schematic representation of an alternative implementation of a dynamic electro-optic prism including a variable resistance electrode.

FIGS. 16A-B show schematic representations of a variable-apex angle prism.

FIG. 17 shows a schematic representation of an alternative implementation of a variable-apex angle prism.

FIG. 18 shows a schematic representation of a variable-refractive index/variable-apex angle prism.

FIG. 19 is a schematic representation of a prism/light focusing element assembly including an infrared filter.

FIGS. 20A-B are schematic representations showing light directing systems, including photovoltaic cells with different absorption properties.

FIGS. 21A-B show cross-sectional views of schematic representations of an electro-optic prism including a photon conversion material.

FIG. 22 shows a block diagram representing a system including a solar powered Stirling engine.

Like reference symbols in the various drawings indicate like elements.

### DETAILED DESCRIPTION

Assemblies and techniques are described to steer light rays, including artificial or naturally occurring light. One application where steering light rays has beneficial effects is in the context of solar energy collection. For illustrative purposes, the assemblies and techniques shall be described in the context of solar rays, however, it should be understood that the assemblies and techniques can be applied in other contexts and to other light sources. The solar energy collection application described herein is but one implementation.

To reduce the cost of manufacturing photovoltaic systems, the amount of photovoltaic material required is preferably minimized. Concentrating captured solar rays onto a photovoltaic cell is one technique for maximizing solar energy collection efficiency, as more sunlight impinges on the photovoltaic cell than would otherwise impinge on its surface area. As described above, conventional solar concentrating arrays generally require adjusting the position of a solar energy collection assembly to track the position of the sun. The assemblies and techniques described herein to steer and concentrate light rays provide for configurations that minimize or eliminate physical adjustment, i.e., pointing, of the solar energy collection assembly.

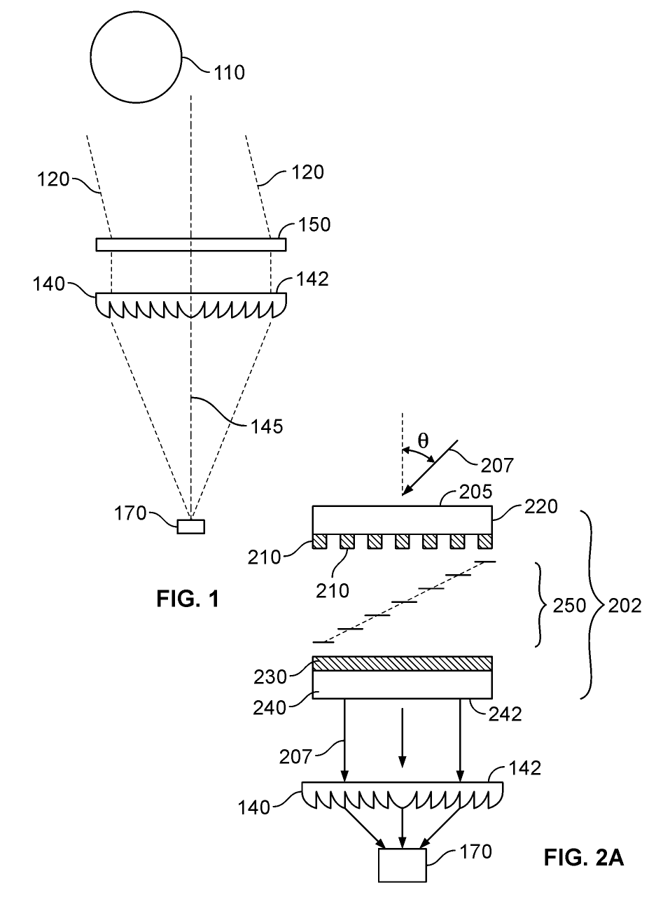

Referring to FIG. 1, a schematic drawing shows a point light source, i.e., the sun 110, which emits a broad spectrum of electromagnetic radiation (solar rays) 120. The sun 110 continuously travels relative to a terrestrial position, such as the location of a photovoltaic cell 170. A light focusing element 140 can receive the solar rays 120 and focus them toward the photovoltaic cell 170 (positioned along the optical axis 145 of the light focusing element 140), thereby concentrating the amount of solar radiation that would otherwise have impinged on the photovoltaic cell 170. To be most effective, however, the solar rays 120 should impinge on a receiving surface 142 of the light focusing element 140 at an approximate 90° angle. That is, to obtain optimal focusing conditions, the point source lies at a point along the optical axis 145 of the light focusing element 140. The optical axis 145 of the light focusing element 140 is generally an axis of rotational symmetry about the light focusing element 140.

The optical axis 145 in most cases is the axis which, given a point light source at a point along the axis 145, would focus or image the light source with a minimum of spherical or chromatic aberrations or coma. If the solar rays 120 impinge on the light focusing element 140 at an angle, other than normal, a significant portion of the solar rays 120 can be refracted away from the absorbing, or active area, of the photovoltaic cell 170, dramatically decreasing the light intensity at the photovoltaic cell 170. The reduction in light intensity has a direct bearing on the overall efficiency of solar energy collection.

A light-steering mechanism 150 can steer incoming solar rays 120, such that solar rays 120 exiting the light-steering mechanism 150 are incident on the receiving surface 142 of the light focusing element 140 approximately normal to the receiving surface 142. The light focusing element 140 can thereby focus a maximum of the solar rays 120 on the photovoltaic cell 170.

In one implementation, the light-steering mechanism 150 includes an electro-optic material configured to direct solar light rays 120 that pass through the light-steering mechanism 150 by means of optical refraction and/or diffraction. The amount of solar light ray steering required, such that light impinges on the receiving surface 142 at normal incidence, depends on the refractive index of the electro-optic material and the size and shape of optical structures included in the light steering mechanism 150, which in turn can vary with an electric potential applied to the material.

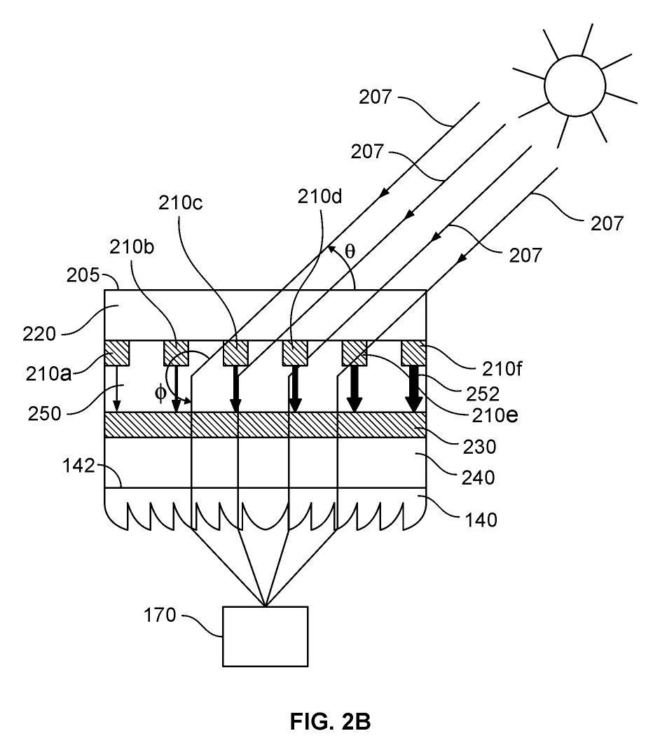

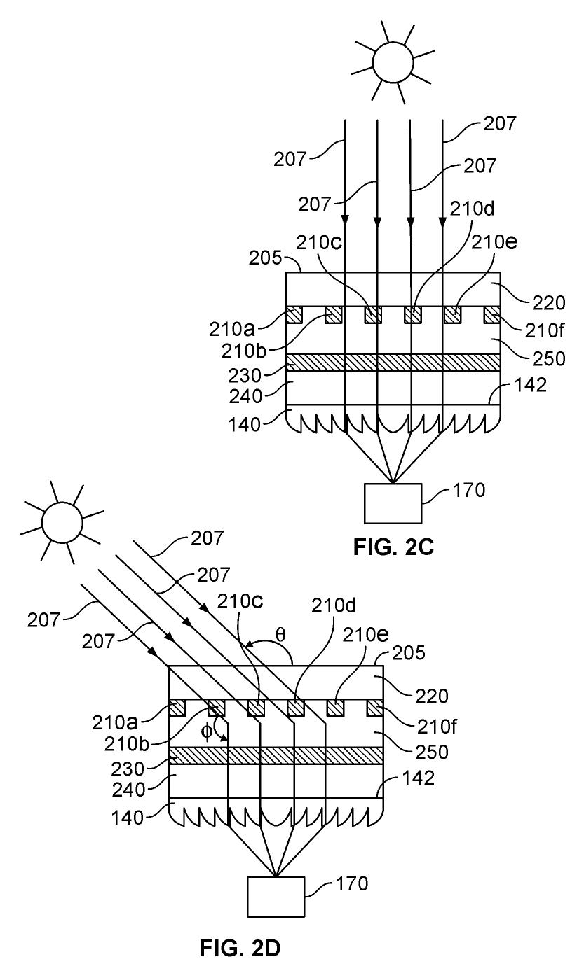

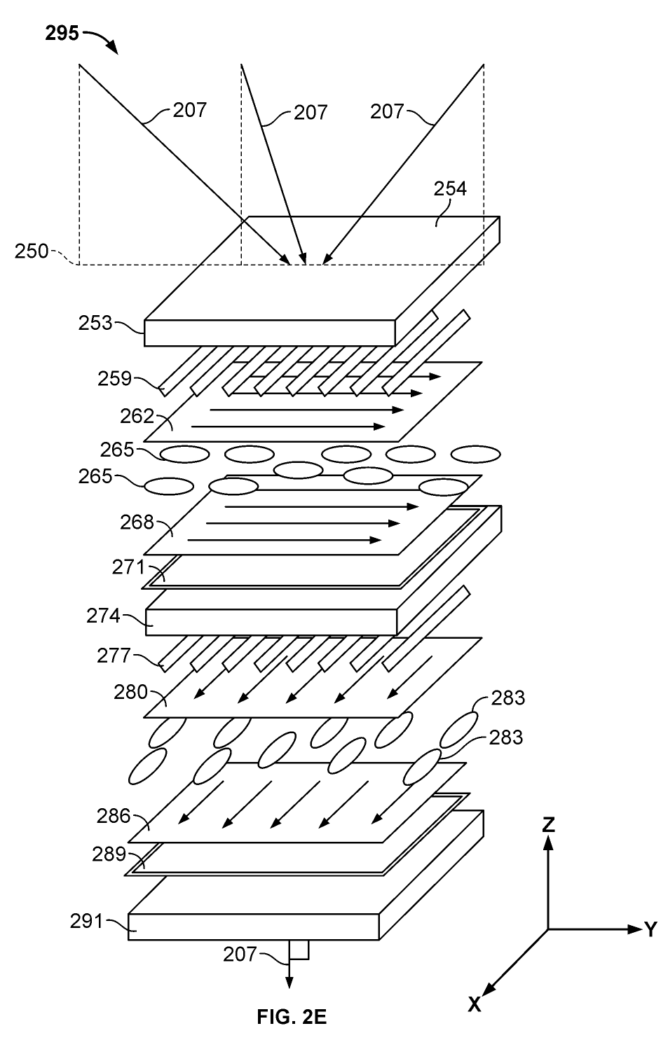

Referring to FIG. 2A, in this implementation, the light-steering mechanism 150 is an electro-optic prism 202. The electro-optic prism 202 can include multiple, individual electrodes 210 on a first substrate 220 and a reference electrode (e.g., a ground electrode) 230 on a second substrate 240. An electro-optic material 250 of substantially uniform thickness is positioned between the electrodes 210 and 230. In one implementation, the electro-optic material 250 can be liquid crystal. In one implementation, the electrodes 210 and 230 are transparent electrodes, for example, formed of indium tin oxide.

Applying voltages to the electrodes 210 generates an electric field in the electro-optic material 250, causing polar molecules therein to rotate in the direction of the applied electric field. In some implementations, the reference electrode 230 is electrical ground. By controlling the voltages to the individual electrodes 210, a gradient in the refractive index (“index gradient”) of the electro-optic material 250 can be created. The index gradient is controlled in accordance with the angle of incident solar rays 207, which can be in accordance with the position of the sun relative to the surface 205 of substrate 220. As the sun moves, i.e., the angle θ in FIG. 2A changes, the index gradient can be controllably modified, such that the incident solar rays 207 are steered from their angle of incidence θ so as to exit the bottom surface 242 of the substrate 240 substantially normal to a receiving surface 142 of the light focusing element 140. The solar rays 207 are therefore incident at an approximate 90° angle on the receiving surface 142 and can thereby properly focused toward the photovoltaic cell 170.

FIGS. 2B-D illustrate an implementation where solar rays 207 are steered throughout the course of a day by a light steering mechanism of the type described above. Light rays 207 can be steered such that they impinge on the light focusing element 140 substantially normal to the receiving surface 142, so that the solar rays 207 can be substantially focused to a photovoltaic 170. In FIG. 2B, solar rays 207 impinge on a receiving surface 205 of a first transparent substrate 220 at an angle θ with respect to the receiving surface 205 of the first substrate 220. In FIGS. 2B-D, the axis of angle θ is at the intersection of solar ray 207 and the receiving surface 205 of the substrate 200; θ=0° when the solar ray 207 is parallel with the receiving surface 205 and increases to the incidence angle of the solar ray 207 when the solar ray 207 impinges non-parallel, as indicated in FIG. 2B. Such is the situation, for example, when the sun rises from the east, from the perspective of a stationary viewer in the northern hemisphere of the earth, looking south. A series of linear, patterned, transparent electrode strips 210a, 210b, 210c, 210d, 210e, and 210f can be formed on the substrate 220, such that the long axes of the electrodes are substantially parallel. An electric field can be applied to an electro-optic material 250 by applying voltages to the electrodes 210a-f, wherein the reference electrode 230, formed on the substrate 240, is electrical ground.

An index gradient can be created in the electro-optic material 250 that bends the solar rays 207 an angle φ as shown in FIGS. 2B-D, by applying successively increasing or decreasing voltages to electrodes 210a, 210b, 210c, 210d, 210e, and 210f. The order of increasing or decreasing voltage applied to electrodes 210a-f can depend on the incidence angle of the solar rays 207, and how much refraction is necessary to bend the solar rays 207 to their target (i.e., the photovoltaic 170). In FIG. 2B, the order of increasing voltage applied to the electrodes 210a-f can increase in the order: 210a, 210b, 210c, 210d, 210e, and 210f for the incidence angle shown. In this implementation, the spatial gradient in index of refraction created in the material 250 is controllable from one side of the electro-optic material 250 (e.g., near electrode 210a) to the other (e.g., near electrode 210f), due to the electric fields created between each of the electrodes 210a-f and the reference electrode 230.

The electric field gradient (and therefore the index gradient) is exemplified in FIG. 2B as arrows 252 between the electrodes 210a-f and the reference electrode 230. In this example, the strength of the electric field is indicated by the width of the arrow, where larger arrows indicate higher electric field. The magnitude of the electric field at each location (each arrow 252) can be governed by the voltage applied to electrodes 210a-f. The electro-optic prism 202 in FIG. 2A is the electro-optical analog of a conventional (e.g. triangular glass or other optical material) prism. The solar rays 207 encountering the index gradient at an angle θ are refracted at an angle φ as shown in FIG. 2B; the magnitude of the index gradient can be controlled via the applied voltages to the electrodes 210a-f, such that the solar rays 207 impinge substantially normal on the surface of light focusing element 140.

As the sun moves to a position substantially normal to the surface of the substrate 220 (thereby increasing the angle θ to substantially 90°), as shown in FIG. 2C, the index gradient can gradually decrease in magnitude by applying appropriate voltages to the electrodes 210a-f. In this circumstance the solar rays 207 can propagate substantially free of angular steering, such that they impinge normal to the receiving surface 142 of the light focusing element 140.

FIG. 2D illustrates the reverse process as shown in FIG. 2B, which occurs as the sun continues its course across the sky. Now, the voltages applied to electrodes 210a-f can increase in the order: 210f, 210e, 210d, 210c, 210b, and 210a. This steers the solar rays 207 an angle φ and can cause the solar rays 207 to impinge substantially normal to the receiving surface 142 of light focusing element 140.

FIGS. 2B-D illustrate how the electro-optic prism 202 can effectively capture solar radiation at a wide range of incidence angles (θ) without necessitating angular adjustment of the receiving surface 205 of the first substrate 220, or other optical components contained within the electro-optic prism 202. By this virtue, referring back to FIG. 1, together, the light steering assembly 150, light focusing element 140, and photovoltaic 170 can remain stationary, yet still capture solar rays 120 throughout the day. This is unlike the conventional solar concentrating systems that necessitate physical movement of the components such that they are always facing the sun.

Liquid crystal molecules have a long axis (usually substantially parallel to their polar axis) that may be set in a selected orientation, i.e., the orientation that the liquid crystal molecules will assume under zero applied electric field, by “brushing” one or more alignment layers (for example, a layer of polyamide). Applying an alignment layer aligns the long axes of the liquid crystal molecules near the adjoining surfaces of the liquid crystal layer (i.e., top and bottom of the liquid crystal layer) under zero external field conditions, and subsequently aligns the liquid crystal molecules throughout the volume of the material. The process of aligning the liquid crystal molecules throughout creates birefringence in the liquid crystal material 250. This effect is well known, and arises out of the difference in which parallel and perpendicular polarization components of light travel through the liquid crystal with respect to the long (or polar) axis of the molecules. In the absence of an applied electric field, light traveling through the liquid crystal (for a given polarization) is primarily steered in a direction governed by the orientation of the liquid crystal molecules, which should be parallel with the alignment layer. Light polarized orthogonal to the liquid crystal director (generally the direction of the long axis of the liquid crystal molecules when they are aligned) experiences substantially no change in refractive index as it passes through the liquid crystal. In most cases, the preferred orientation of the director (when no field is applied) is perpendicular to the electric field, when created.

FIG. 2E shows an exploded view of one implementation of a light steering mechanism 295 configured to steer solar rays 207 (propagating in a plane 250) incident on a first substrate 253. The substrate 253 can be transparent and can have attached thereto a series of linear transparent electrode strips 259 oriented in a selected direction, in this example, along the indicated x-axis. A top liquid crystal alignment layer 262 is applied to the substrate 253/electrode 259 surface and brushed in a selected direction (in this example the y direction), which orients a layer of liquid crystal 265 in the same direction. A second, bottom liquid crystal alignment layer 268 is brushed in the same direction as the top liquid crystal alignment layer 262, to ensure total and rapid liquid crystal alignment (under zero externally-applied electric field).

The electrode 271 is supported by a second substrate 274, which can be substantially transparent. A layer of linear electrodes 277 similar to 259 is attached to a lower surface of the substrate 274. In contact with the substrate 274/electrodes 277 surface is a brushed liquid crystal alignment layer 280 that can be perpendicular to the direction of the liquid crystal alignment layers 262 and 268. The brushed liquid crystal alignment layers 280 and 286 form the top and bottom layers respectively of a liquid crystal layer 283. In this case, the direction of the liquid crystal molecules included in the liquid crystal layer 283 is orthogonal to the liquid crystal molecules included in the liquid crystal layer 265. A bottom electrode 289 is supported by a transparent substrate 291 and is in contact with the bottom liquid crystal alignment layer 286.

The light steering mechanism 295 shown can steer an unpolarized light ray 207 that impinges on the surface 254 of the substrate 253 at an angle, such that the light ray 207 exits the bottom substrate 291 substantially normal, as shown. As it is illustrated in FIG. 2E, the light steering mechanism 295 only steers light in one direction, that being orthogonal to the direction of the long axis of the electrodes 259 and 277. Light rays 207 with polarization vectors orthogonal to the first liquid crystal layer 265 pass through the layer 265 unchanged in direction, while those with some degree of parallelism with the liquid crystal layer 265 undergo some degree of refraction due to the index gradient. The orthogonal rays can be refracted at the second, orthogonally-aligned liquid crystal layer 283 (with respect to the first liquid crystal layer 265).

If the light rays 207 impinge normal to the receiving surface 254 of the substrate 253, the electrodes can be turned off, and light will pass straight through, emerging normal to the bottom substrate 291.

To allow for two-axis light ray steering, the light steering assembly 295 can be cloned, placing one light steering assembly 295 on top of the other, such that the direction of the long axes of the patterned electrodes 259, 277 in the light steering mechanism 295 are perpendicular to the long axes of the linear electrodes included in the second light steering mechanism. As light rays are steered orthogonal to the long axes of the linear electrodes 259, 277, unpolarized light ray steering in any direction can be accomplished by this approach.

An embodiment of an electro-optic prism can include, for nematic liquid crystal, all or some of the elements in FIG. 2E. An embodiment of an electro-optic prism can include, for cholesteric liquid crystal, all or some of a substrate 253, electrodes 259, liquid crystal alignment layer 262, liquid crystal layer 265, liquid crystal alignment layer 268, electrode 271, and substrate 274. For electro-optic prisms using cholesteric liquid crystal, a second layer of orthogonally-aligned liquid crystal is not necessary to steer light in one direction (as is shown for the light steering mechanism 295 in FIG. 2E), but may be used in some situations, since an index gradient within a cholesteric liquid crystal layer can refract unpolarized light.

In one implementation, a solar energy collection assembly, such as that described in reference to FIGS. 2A-E above, can use a portion of the collected solar energy for providing the voltages applied to the electro-optic material 250.

Because optical switching speed is not a significant factor in solar steering applications, i.e., the speed at which the liquid crystal molecules align under the influence of the applied electric field, thicker layers of electro-optic material 250 as compared to layers used in other applications can be desirable, as a thicker layer allows for a greater optical phase delay, making larger angular deflections possible.

Dynamic electro-optic prisms and static prisms described herein can be of either a refractive or diffractive nature, depending on their design and construction, and the implementations described may include either prism type. A difference between the two is that a refractive prism steers light using structures (e.g., electrodes) of a relatively large size compared to the wavelength of light, while diffractive structures steer light using structures of a relatively comparable size to the wavelength of light. The behavior of refractive devices can be adequately described using Snell's law, while the wave nature of light is used to describe the behavior of diffractive devices.

Referring again to FIG. 2A, an electric field is created in the electro-optic material 250 when a voltage is applied to the electrodes 210, and the electrode 230 is a ground electrode. The electrodes 210 can be linear strips of transparent conducting material. The linear electrodes 210 can be formed using any convenient technique, for example, by photolithography, chemical etching, and the like. The ground electrode 230 can also be a transparent electrode, and in one implementation can be similarly constructed of linear strips of conducting material, or in another implementation, can be a contiguous planar material. In the latter case, the electrodes may be formed by techniques known by those skilled in the art of making planar transparent electrodes, such as by chemical vapor deposition (CVD), sputtering, spin-coating, and the like. In one implementation, the electrodes 210 and 230 are formed from indium tin oxide.

When refraction of incident light rays 207 is desired, such as that shown in FIG. 2A, it is desirable to space the linear strips of transparent electrodes 210 a distance that minimizes diffraction of the light rays 207. Diffractive effects become more prominent when the spacing of a gradient approaches the wavelength of incident light. In one implementation, such as that shown for FIG. 2A, the spacing of the electrodes 210 is on the order of three to five microns apart, and the width of each electrode (e.g., each linear electrode 259 in FIG. 2E) can be of the same scale. The length of the electrodes 210 can extend to the boundaries of the substrate 220. In one implementation, a length of the electrodes 210 can be from six to thirty centimeters.

In certain implementations, a contiguous electrode, rather than strips of individual electrodes, can be used to create the index gradient in the electro-optic material. For example, a variable resistance electrode can be used, which is discussed further below. In this case, the index gradient can be formed by the potential drop from a first end to a second end when voltage is applied to the first end. The index gradient can be formed in a selected direction by applying the driving voltage to a selected end of the variable resistance electrode and grounding the other end. In this manner, sunlight from one direction can be refracted in a selected direction by applying the driving voltage to one end of the variable-resistance electrode. The end to which the driving voltage is applied is then reversed when light rays are incident from the opposite angle.

In other implementations, a variable-thickness electrode can provide the index gradient. A variable-thickness electrode will produce a potential drop from one end to which the driving voltage is applied due to its increasing thickness. The variable-thickness electrode can be placed on a solar ray-receiving surface of a substrate and is substantially transparent. A variable-thickness electrode composed of transparent conducting material can be formed on a substrate by various means known to those skilled in the art, including CVD, dipping, or sputtering.

### Light Ray Steering

To employ an electro-optic prism to steer solar rays from their angle of incidence to a desired orientation, e.g., orthogonal to a receiving surface of a light focusing element, information about the sun's position is required. The sun's position can be used to estimate the angle of incidence, and thereby provide the electro-optic prism with an appropriate index gradient through application of an electric field. The sun's position can be tracked using any convenient technique, including programming control electronics for the electro-optic prism with pre-determined solar coordinates (i.e., elevation and azimuthal angles) and/or continuous, active tracking of the sun's position using optical detectors and associated electronics in a feedback mode.

In one implementation, the amount of solar energy collected by a photovoltaic cell can be monitored by associated circuitry; the application of the electric field to the electro-optic prism can be integrated into a feedback mechanism. The index gradient of the electro-optic prism can be continually adjusted to provide maximum energy absorption by the photovoltaic cell, based on the information provided by the photovoltaic cell monitor.

Additionally, as discussed above, the light steering assemblies and techniques described herein can be used to steer light rays emanating from a light source other than the sun. If the light source is mobile, similar techniques as described above for solar ray tracking can be employed to track movement of the light source relative to the light steering assembly.

### Dynamic Variable-Power Electro-Optic Prism

Referring again to FIG. 2A, the applied voltage applied across the electrodes 210, 230, affects the strength of an electric field generated in the electro-optic material 250 near each electrode. By independently controlling the electric field strength at each electrode, a refractive index gradient can be formed in the electro-optic material 250. By controlling the refractive index of the electro-optic prism, the electro-optic prismatic effect can be used to steer the solar rays 207. In the implementation shown, the solar rays 207 are steered to normal incidence on the light focusing element 140 as the sun moves overhead, by varying the strength of the electric field and therefore the index gradient of the electro-optic prism 202.

The arrow between the reference electrode 230 and the light focusing element 140 does not necessarily imply a physical space between the two elements; in some implementations the electrode 230 is deposited directly upon a surface of the light focusing element 140.

### Electro-Optic Materials

In one implementation, the electro-optic material 250 is liquid crystal. The index of refraction of liquid crystal can be altered to a maximum saturation depending on the applied electric field. If the liquid crystal layer then experiences a gradient in the refractive index due to a gradient in the electric field, an optical refractive or diffractive effect can occur, resulting in a modification of the phase of a light wavefront. This effect can be used to focus, steer, or correct arbitrary wavefronts, thereby correcting for aberrations due to light propagation through the material. In this sense, liquid crystal cells configured as shown in FIG. 2A can be referred to as electro-optic prisms, since they effectively steer light a given amount proportional to an induced index gradient provided by an external voltage.

Prismatic power is generally a measurement of the magnitude of the refraction or diffraction angle that a light ray undergoes by passing through (or diffracting in) a prism. In most cases, light undergoes a higher degree of refraction (more prismatic power) for prisms formed of materials of high dispersion, i.e., optical index.

As discussed, liquid crystals are generally elongated, polar molecules that tend to align axially with one another along their longitudinal axis. This property of liquid crystals can be used to define a bulk direction of alignment in a liquid crystal device. The direction of the local molecular alignment is referred to as a director as described above. Due to these alignment properties, nematic liquid crystal is a birefringent material, and to steer unpolarized light, such as sunlight, two liquid crystal layers having orthogonally arranged alignment directions are typically used. That is, the direction of alignment of the liquid crystal layer in one electro-optic prism is at approximately a 90° angle to the director of the second liquid crystal layer in the second electro-optic prism when no power is applied, as shown in FIG. 2E. By way of example only, a suitable liquid crystal is BL037, available from Merck Co., Germany.

To provide the largest possible range of refractive angles, liquid crystals that exhibit relatively large differences in refractive index between zero electric field and that at saturation (i.e., they are highly birefringent) can be used, and should display low chromatic dispersion. For example, a preferred range of the change in index of refraction provided by a liquid crystal layer can be from approximately 0.3 to 0.4. BL037 liquid crystal has an effective range in refractive index of 0.28.

In one implementation, a cholesteric liquid crystal material can be used in an electro-optic prism. Cholesteric liquid crystal exhibits chirality, and the director is not fixed in a single plane, but can rotate upon translation through the material. In certain configurations a cholesteric liquid crystal layer can be substantially polarization insensitive. Accordingly, an electro-optic prism including a single layer of cholesteric liquid crystal can be used to steer unpolarized light with high efficiency. Reducing the number of layers of liquid crystal can reduce undesirable transmission loss. A stronger electric field, hence higher voltages, can be required to rotate the molecules of a cholesteric liquid crystal as compared to a nematic liquid crystal. However, since a single layer is capable of affecting both light polarizations of the solar rays, using cholesteric liquid crystal can still improve efficiency.

In another implementation, bistable liquid crystal can be used. The director of a bistable liquid crystal has two or more orientations that can be induced by application of an electric field and that remain (i.e. they are stable) after the field is removed. The result of bistable states is that when the electrical power is turned off, the prismatic effect remains, thereby minimizing the amount of electrical energy needed for the electro-optic prism.

For example, a certain voltage can be required to align liquid crystal molecules in an electric field according to their dipole moment. When that voltage is applied to a bi-stable liquid crystal, the liquid crystal molecules rotate in the field; at that point, the voltage can be turned off and the liquid crystal molecules retain their orientation. This has the benefit of reducing the energy required to keep the liquid crystal molecules in a particular orientation to affect a given steering of incoming light rays. This configuration can be particularly useful in a situation where the movement of the point light source is relatively minor, such as points on the earth near to either geographic pole. By way of example only, bistable liquid crystals can include surface stabilized ferroelectric liquid crystals (SSF liquid crystal).

In one implementation, stacked electro-optic prisms can be used where the electro-optic materials, i.e., liquid crystal layers 265 and 283 in FIG. 2E, are different, thereby providing different magnitudes of prismatic power when the index gradient is created. In certain implementations, a top electro-optic material, e.g., layer 265 can provide a filtering effect if its light absorption properties are different than that for layer 283. Unwanted or undesirable wavelengths can then be absorbed by the first layer 265, allowing desired wavelengths to continue propagating to layer 283, where they are steered in a preferable direction.

### Electro-Optic Prism/Light Focusing Element Assemblies

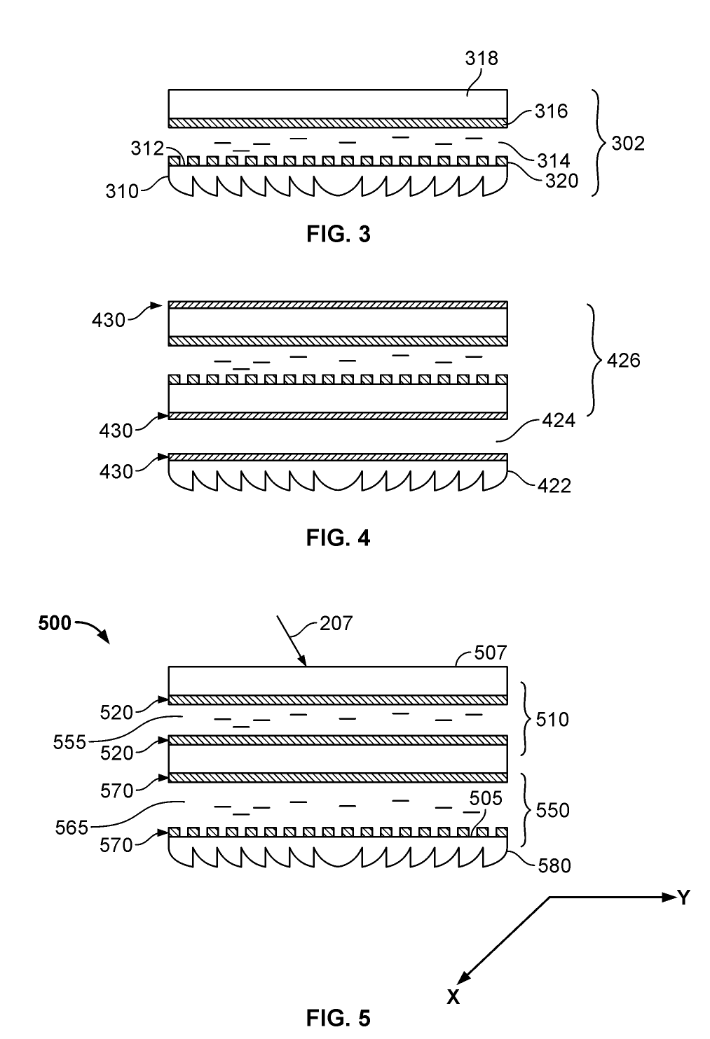

Referring to FIG. 3, in one implementation, an electro-optic prism (e.g., 202 in FIG. 2A) 302 and a light focusing element 310 can be constructed monolithically. In this implementation, the light focusing element 310 is a Fresnel lens. The receiving surface 312 of the Fresnel lens 310 can be used as a substrate to support the parallel, linear electrodes 320. The electro-optic material 314 and a substrate 318 supporting the second electrode 316 are positioned on top of the electrode 320. If additional electro-optic prisms are desired, e.g., a second prism arranged with the liquid crystal alignment direction orthogonal to a director of the first prism, they can be constructed similarly beginning with an electrode being deposited on a upper surface of the substrate 318 followed by a liquid crystal layer and an electrode. The second prism can be positioned above or below the first prism, e.g., in a stacked arrangement. Note that in FIG. 3, the linear strips of transparent electrodes 320 are below the planar transparent electrode 316, the opposite of that shown, for example, in FIG. 2A. In some implementations, this arrangement can be used and can result in the same effect on the electro-optic layer 314.

The Fresnel lens 310 can be configured for point or line concentration. For point concentration, the Fresnel lens 310 is a spherical lens and for line concentration the Fresnel lens is a cylindrical lens.

Referring to FIG. 4, in one implementation a gap 424 is maintained between an electro-optic prism (e.g. 202 in FIG. 2A) 426 and a light focusing element 422. The gap 424 can provide air circulation to cool the electro-optic prism 426. Anti-reflective coatings 430 can be used to reduce reflection losses on the surfaces of the electro-optic prism 426 elements and/or the light focusing element 422. In some implementations, an anti-reflective coating can be included on one or more surfaces in the electro-optic prism and/or light focusing element, whether constructed separately or as an assembly, to minimize loss due to reflections. By way of example only, anti-reflective coatings can be placed on the outermost surface of the device and are fabricated from one or more layers of refractory oxides (e.g. SiO₂, Al₂O₃, ZrO₂) having a thickness of approximately ¼ of an optical wavelength. However, anti-reflective coating can be placed at the interface between any two optical materials whose refractive indices are not equal to help eliminate reflective losses.

### Two-Axis Steering

FIG. 5 shows an implementation of an electro-optic prism/light focusing element assembly 500 including two dynamic variable-power electro-optic prisms (e.g., 202 in FIG. 2A) 510, 550, overlaid and orthogonally aligned with respect to the linear electrode long axis direction. A first dynamic variable-power electro-optic prism 510 (having electrodes 520, which can be planar electrodes, linear electrodes, or a combination of both) is arranged with the prism base along the y-axis and the second dynamic variable-power electro-optic prism 550 (having electrodes 570) is arranged with the prism base along the x-axis. This arrangement can provide for two-axis steering, for example, to allow north-south as well as east-west steering as has been previously discussed.

In one implementation, solar rays 207 impinge on a receiving surface 507 of a first electro-optic prism 510 and are refracted or diffracted at an angle to compensate for the north-south angular deviation from normal with respect to the receiving surface 505 of the light focusing element 580. The refracted or diffracted solar rays 207 next encounter the second electro-optic prism 550, wherein the second prism's electrodes 570 are aligned orthogonal to the first prism's electrodes 520. The solar rays 207 are now affected by the second electro-optic prism such that an angular correction is made for east-west angular deviation. The solar rays 207 now continue and impinge on a receiving surface 505 of the light focusing element 580 at a substantially 90 degree angle to the receiving surface 505 of the light focusing element 580.

In one implementation, each of the two dynamic variable-power electro-optic prisms 510, 550 shown in FIG. 5 use nematic liquid crystal as the electro-optic material. Accordingly, to account for the unpolarized nature of sunlight, each of prisms 510 and 550 can include two nematic liquid crystal layers in each of the electro-optic material layers 555, 565 having orthogonally arranged directors. In another implementation, each dynamic variable-power electro-optic prism 510, 550 uses a single layer of cholesteric liquid crystal as the electro-optic material 555, 565, respectively.

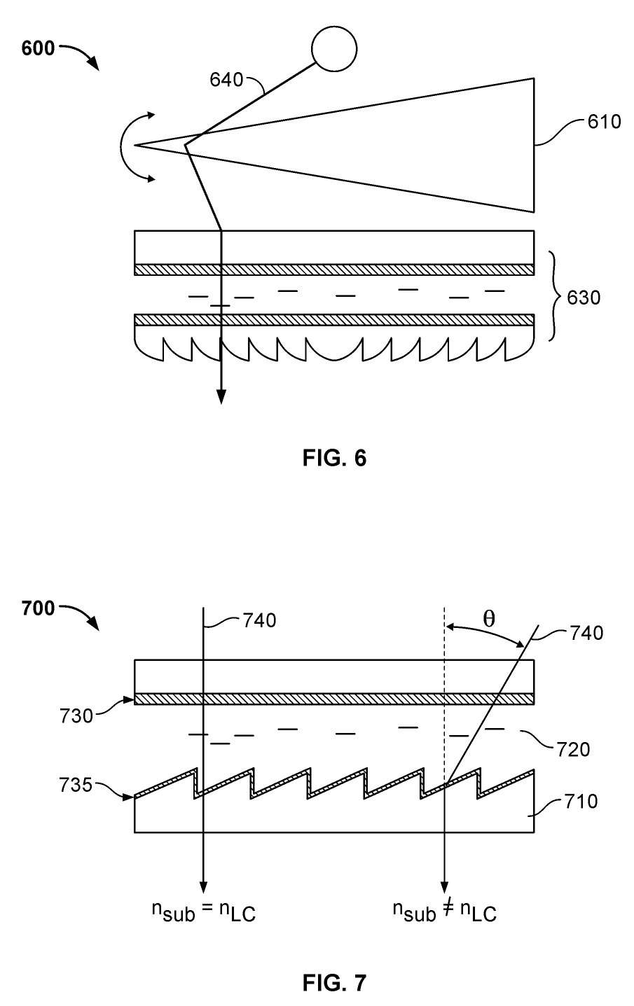

Referring to FIG. 6, another implementation of an assembly 600 that can provide two-axis light steering is shown. In this implementation, a dynamic variable-power electro-optic prism (e.g., 202 in FIG. 2A) 630 is used in combination with at least one static fixed-power prism 610. In one implementation, the dynamic variable-power electro-optic prism 630 and the static fixed-power prism 610 are arranged such that the prisms steer solar rays 640 in orthogonal directions. For example, north-south steering can be performed manually by periodic seasonal adjustment of the static fixed-power prism 610, and east-west steering can be performed with the dynamic variable-power electro-optic prism 630, as has been described above for diurnal adjustment. The assembly 600 can include parallel, linear electrodes to generate an index gradient as was described for the electro-optic prism 202 in FIG. 2A.

In another implementation, the dynamic variable-power electro-optic prism 630 and the static fixed-power prism 610 are arranged such that the prisms steer solar rays in the same direction. The static fixed-power prism 610 can be used for coarse steering and the dynamic variable power electro-optic prism 630 can be used for fine steering.

In one implementation, the static fixed-power prism 610 is a conventional refractive/diffractive optical element, such as a glass prism, mounted upon a mechanism that provides support and angular adjustment of the prism 610. “Glass” can encompass any of the well-known materials used in the art for refracting or diffracting light, such as “quartz glass,” SF10, liquid crystalite, etc.

In addition to layering dynamic variable-power electro-optic prisms to achieve two-axis light steering, the prisms can be layered to provide a larger, incrementally additive prismatic power when each layer is activated electrically (i.e., “turned on”). The combined dynamic variable-power electro-optic prisms can increase or decrease their overall prismatic power as required, effecting the desired angular solar ray steering.

In some implementations, it may be advantageous to combine electro-optic ray steering with a fixed deflection component, for example, the static fixed-power prism 610 shown in FIG. 6. Thus, various combinations of dynamic variable-power electro-optic prisms and static fixed-power prisms can be used to reduce the required dynamic angular range of the electro-optic prisms.

### Dynamic Fixed-Power Electro-Optic Prism

Referring to FIG. 7, a variation of the dynamic variable-power electro-optic prism described above for FIG. 6 is the dynamic fixed-power electro-optic prism 700. In this implementation, a static fixed-power prism (or array of prisms) 710 is positioned in contact with a layer of electro-optic material, e.g., a liquid crystal layer 720. Electrodes 730, 735 are included on opposing surfaces of the liquid crystal layer 720 to apply an electric field, as described above. In one implementation, one of the electrodes is electrical ground, e.g., electrode 735.

The dynamic fixed-power prism 700 has two modes: an “on” mode and an “off” mode. That is, in the “on” mode, a fixed electric potential is applied across the electrodes 730, 735, generating an electric field in the liquid crystal layer 720, resulting in light being steered in a first direction. In the “off” mode, no electric potential is applied across the electrodes 730, 735, resulting in light being steered in a second direction, or not steered at all if the liquid crystal layer 720 and the fixed-power prism 710 are index-matched. The voltage applied to the electrodes 730, 735 is either on or off, resulting in light being steered in one of two fixed directions (or allowed to propagate straight through in the index-matched case), thus the term “dynamic fixed-power prism.”

The liquid crystal layer 720 can be index-matched in either the “on” or “off” mode to the material forming the static fixed-power prism 710. When index-matched, there is no prismatic power. In the mismatched mode, i.e., the refractive indices of the liquid crystal layer 720 and static fixed-power prism 710 are different; the dynamic fixed-power electro-optic prism diffracts/refracts light at a fixed angle determined by the blaze angle of the static fixed-power prism 710. In one implementation, a pair of dynamic fixed-power electro-optic prisms are oppositely positioned in a stacked arrangement to provide a gross angular steering correction for two quadrants of the sky, e.g., to provide steering of solar rays emanating from both the east and the west. The electrodes 730, 735 in this implementation can be contiguous, as they are only used to provide a change in the index of refraction of the liquid crystal layer 720.

In another implementation, a dynamic variable-power electro-optic prism (e.g., 202 in FIG. 2A) can be added to a stack of dynamic fixed-power electro-optic prisms 700, where the dynamic variable-power electro-optic prism provides “fine tuning” of light ray steering, in addition to the coarse light ray steering provided by the dynamic static-power electro optic prisms 700.

In an implementation using cholesteric liquid crystal as the electro-optic material in the various prisms, a stacked assembly includes at least three electro-optic prisms: one dynamic variable-power electro-optic prism (e.g., 202 in FIG. 2A) and two dynamic fixed-power electro-optic prisms 700. Only one dynamic variable-power electro-optic prism is required, since the dynamic variable-power electro-optic prism can be provided with voltages to refract solar rays from two directions, e.g., from either east or west.

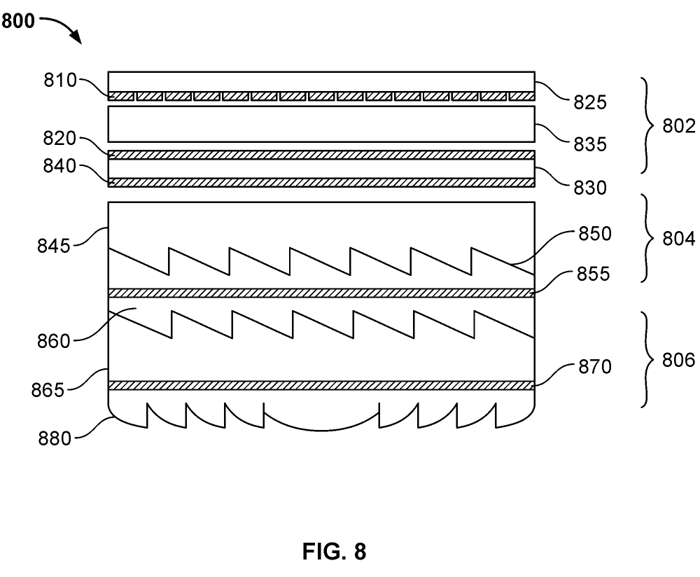

Referring to FIG. 8, an implementation including a dynamic variable-power electro-optic prism (e.g., 202 in FIG. 2A) 802 in combination with two dynamic fixed-power electro-optic prisms (e.g., 700 in FIG. 7) 804, 806 is shown. In this implementation, the electro-optic material for each prism can be cholesteric liquid crystal. The dynamic variable-power electro-optic prism 802 can be fabricated monolithically with the dual-etched dynamic fixed-power electro-optic prisms 804, 806.

The dynamic variable-power electro-optic prism 802 can include a drive electrode 810 affixed to a substrate 825 and a reference electrode 820 affixed on an electrode substrate 830. A liquid crystal layer 835 can be positioned between the reference electrode 820 and the drive electrode 810.

A drive electrode 840 for the first dynamic fixed-power electro-optic prism 804 can be formed on the opposite side of the electrode substrate 830 as the electrode 820 for the dynamic variable-power electro-optic prism 802. A layer of liquid crystal 845 is positioned on a static fixed-power prism 850, which itself is positioned on a reference electrode 855 for the first dynamic fixed-power electro-optic prism 804.

A second dynamic fixed-power electro-optic prism 806 shares the reference electrode 855 with the first dynamic fixed-power electro-optic prism 804. A static fixed-power prism 860 is positioned under the reference electrode 855 and adjacent a liquid crystal layer 865. A second drive electrode 870 is positioned thereunder. The electrodes 870 and 855 can be contiguous to solely provide a change in the refractive index of the liquid crystal layer 865.

The above described elements can be supported by a light focusing element 880, for example, a Fresnel lens.

In some implementations, one or more additional layers of electro-optic prisms can be used to produce a desired range of solar ray steering. In some implementations, it can be desirable that the maximum refraction magnitude of a dynamic variable-power electro-optic prism be equal to the magnitude of the largest dynamic fixed-power electro-optic prism.

### Combined Physical and Light Steering Adjustment

In one implementation, the angular physical orientation of the solar energy collection assembly is adjusted using either a manual or automatic adjuster, in combination with light steering using one or more electro-optic prisms. The one or more electro-optic prisms can be dynamic variable-power electro-optic prisms, dynamic fixed-power electro-optic prisms, or a combination of both. A mechanical tracker can be used to provide some angular physical orientation adjustment. The mechanical tracker does not necessarily need to achieve high accuracy and can be of reduced cost. In one implementation, the mechanical adjuster provides coarse solar ray tracking and the one or more electro-optic prisms provide fine solar ray steering. In another implementation, the adjuster provides solar ray tracking along one axis, for example, in a north-south direction, and can be adjusted seasonally, and the one or more electro-optic prisms provide diurnal solar ray steering in an east-west direction.

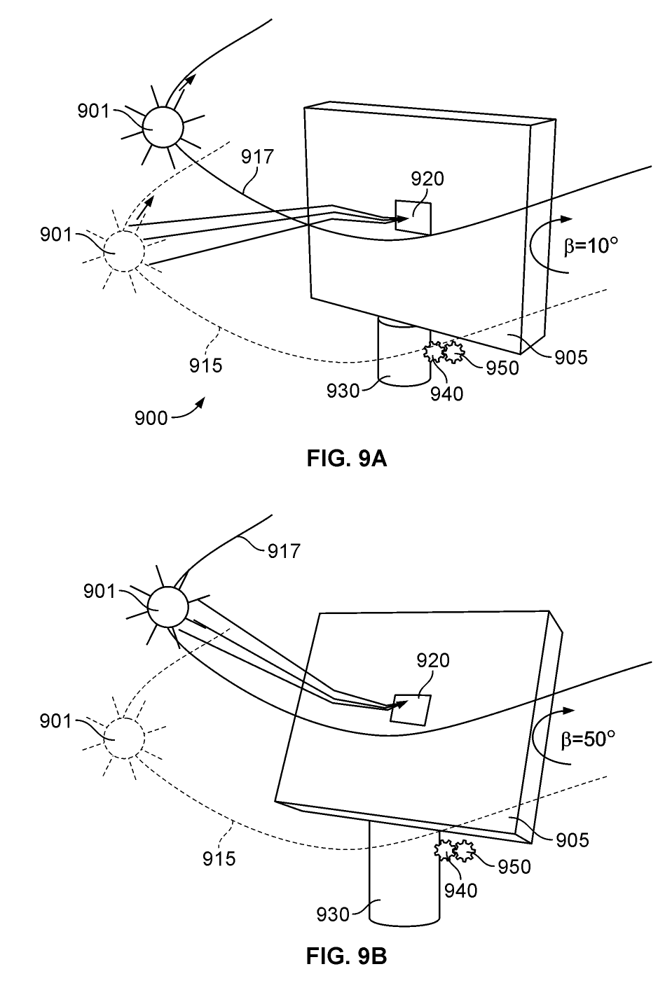

Referring to FIG. 9A, a schematic representation of one implementation of a system 900 including a dynamic variable-power electro-optic prism/light focusing element assembly (e.g., 202 in FIG. 2A) 905, a photovoltaic cell 920, and an adjuster 930 are shown. In this implementation, the adjuster 930 includes a rotatable support that, for example, can tilt the assembly 905 in elevation, an angle β. The elevation angle β can be adjusted, for example, to account for seasonal variation in the elevation of the sun relative to the horizon, for a terrestrial observer. For example, the path 915 of the sun is shown for one part of a year where the elevation angle β of the sun 901 is low. The elevation angle β can be set using the adjuster 930 such that the assembly 905 is pointing at the sun 901, with respect to the sun's elevation. The variable-power electro-optic prism component can compensate for the daily travel of the sun 901 in the daily azimuthal (e.g., east-west) direction, directing light rays impinging on the assembly to the photovoltaic 920, as has been discussed above. At a different time of year, as illustrated in FIG. 9B, the sun's elevation can be higher (as shown for path 917); at this time, the tilt angle β of the assembly 905 can be re-positioned to compensate for the increase in elevation of the sun relative to the horizon.

In another implementation, the axes for each steering mechanism can be reversed, with the mechanical steering adjusting for diurnal sun position. Any suitable mechanism to rotate an electro-optic prism 910 supporting assembly 905 can be used, for example, a gear assembly 940 as shown, which can be driven by a motor (not shown) or a manual hand crank 950 as shown. The implementation shown is a simplified system for illustrative purposes, and other configurations of physical tracking devices can be used.

### Elongated Solar Energy Collection Assembly

In one implementation, an elongated strip of photovoltaic element can be used instead of a round or square element. In this implementation, the solar energy collection assembly can include several elongated Fresnel lenses with cylindrical focusing properties (as compared to a number of individual spherical-focus Fresnel lenses), the lenses arranged in separate rows or columns which are parallel to one another. One or more electro-optic prisms, such as a dynamic variable-power electro-optic prism, a dynamic fixed-power electro-optic prism or a combination thereof, receive solar rays and steer them in an orthogonal direction to the receiving surfaces of the Fresnel lenses. One or more elongated photovoltaic elements are positioned beneath the Fresnel lenses and receive concentrated solar rays therefrom.

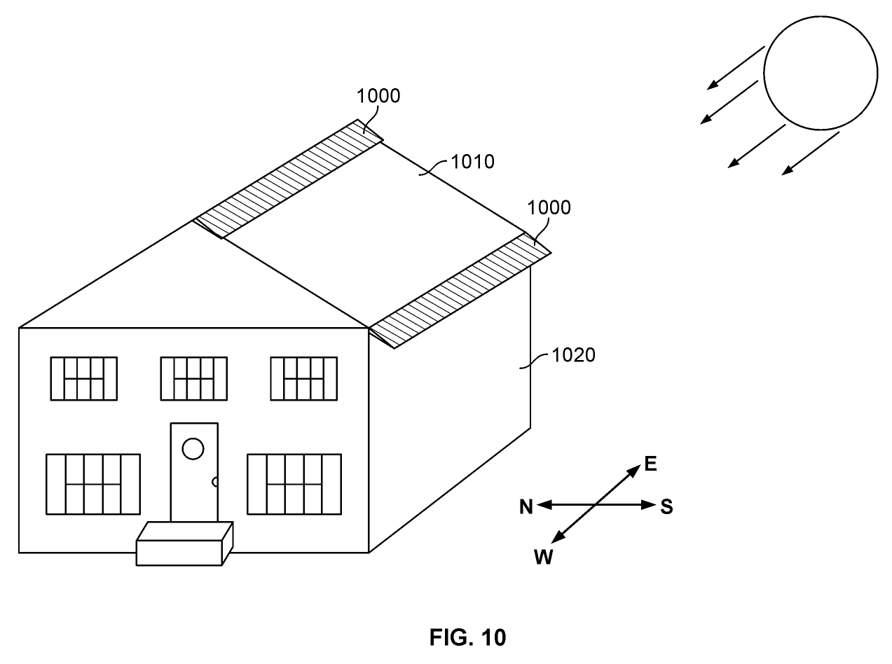

In one implementation, the need for solar ray tracking and steering in one direction can be eliminated if the elongated solar energy collection assembly is axially aligned in the direction. For example, referring to FIG. 10, the solar energy collection assembly 1000 is positioned along the length of a roof 1010 of a building 1020. The roof 1010 runs in an east-west direction, and the solar energy collection assembly 1000 is thereby axially aligned in the east-west direction. Accordingly, as the sun passes over the building 1020 in the course of a day, at least some portion of an elongated photovoltaic element included within the assembly 1000 is exposed to and receives solar rays. Accordingly, light steering in the east-west direction can be eliminated. The one or more electro-optic prisms can be used to correct for seasonal variations in the north-south direction.

### Electro-Optic Prism/Mirror Assembly

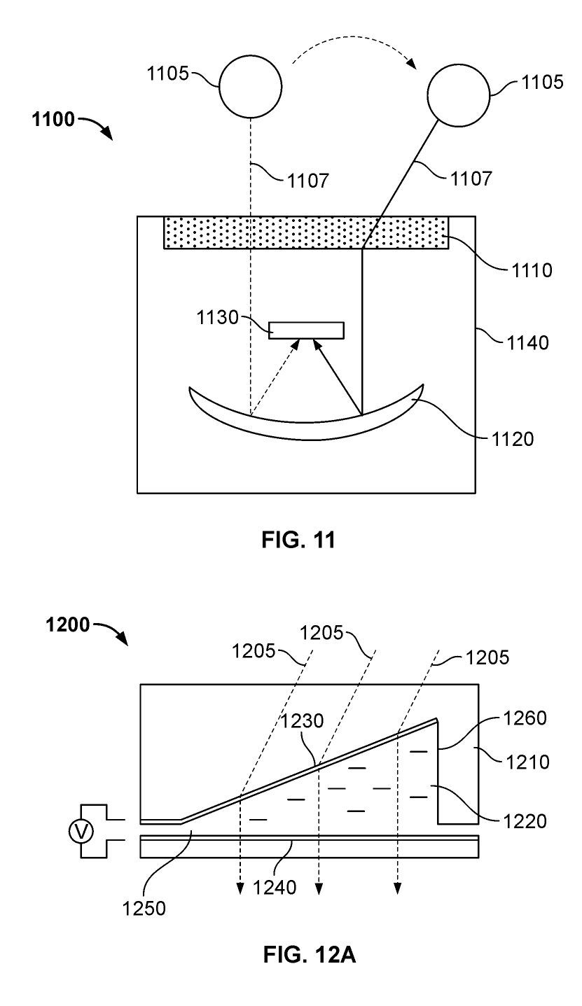

Referring to FIG. 11, a solar energy collection assembly 1140 is shown for collecting solar energy emanating from the sun 1105. In some implementations, a light focusing element 1120 included in a solar energy collection assembly can be a curved mirror, where the mirror focuses light rays 1107 onto a photovoltaic 1130 after being properly steered by an electro-optic prism 1110, e.g., electro-optic prism 202 in FIG. 2A. The light focusing element 1120 can be positioned in optical communication with an electro-optic prism 1110. In some implementations, the electro-optic prism 1110 can be configured according to the various configurations described herein. Refracted solar rays 207 exiting the electro-optic prism 1110 are incident on the curved mirrored surface 1120 and then concentrated toward the photovoltaic element 1130.

### Lensing

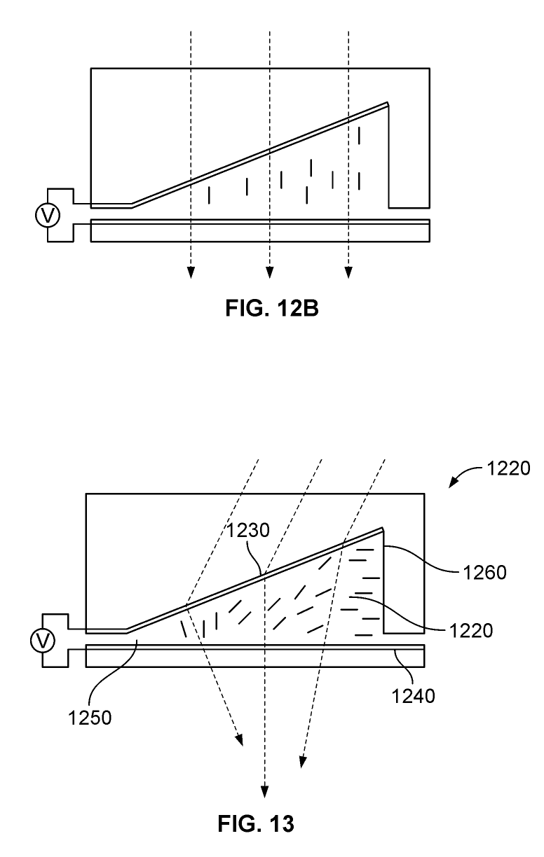

Referring to FIGS. 12A and 12B, a cross-sectional view of one implementation of a dynamic electro-optic prism 1200 is shown. The dynamic electro-optic prism 1200 includes an electro-optic material 1220 having a substantially triangular cross-section. In one implementation, the electro-optic material 1220 is liquid crystal. The index of refraction of the electro-optic material 1220 can be tuned continuously between a minimum and maximum value by applying a selected electric field strength across the electro-optic material 1220, thereby tuning the beam deflection angle.

At one extreme, the difference between the refractive indices of the electro-optic material 1220 and the surrounding medium 1210 is maximized and an incident light ray undergoes a maximum angular deflection. At the other extreme, the refractive indices of the electro-optic material 1220 and surrounding medium 1210 are matched, and an incident light ray undergoes substantially zero deflection, as shown in FIG. 12B.

The difference between the dynamic electro-optic prism shown in FIGS. 12A and 12B is the application of an electric potential and the resulting effect on light refraction. The entrance and exit faces of the electro-optic material 1220 can be coated internally or externally with a thin layer of transparent conductor (e.g., indium tin oxide) to form planar electrodes 1230 and 1240. As discussed above, when an electric potential is applied across the two electrodes 1230, 1240, an electric field is generated internal to the electro-optic material 1220. When the electro-optic material is liquid crystal, the liquid crystal molecules, which can be initially oriented perpendicular to the electric field, rotate in the direction of the electric field. The higher the voltage, the stronger the electric field intensity, and the greater the change in the refractive index from the zero-field state. In a solar ray steering application, two such prisms 1200 arranged with the liquid crystal alignment directions orthogonal to one another can be used to steer all of the incoming solar rays to overcome the unpolarized nature of sunlight.

As discussed, lensing is an effect that can negatively impact the light steering performance of an electro-optic prism, such as an electro-optic prism 1200 having the configuration shown in FIG. 12A. If the separation of the electrodes 1230, 1240 is substantially constant, then the electric field strength within the electro-optic material 1220 is substantially homogeneous. However, because of the triangular cross-section of the electro-optic material 1220, the separation of the electrodes 1230, 1240 varies linearly from the apex 1250 to the opposing edge 1260 of the electro-optic material 1220. Because the electric field strength varies across the electro-optic material 1220, the refractive index also varies. Referring to FIG. 13, the effect of an inhomogeneous electric field and therefore a non-linear index gradient across the electro-optic material 1220 is shown.

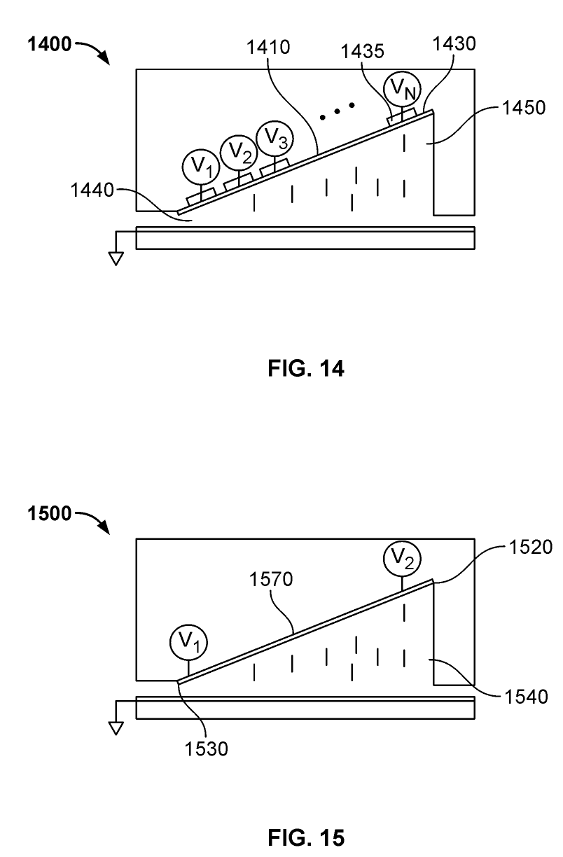

In one implementation, the deleterious effects of lensing can be substantially eliminated by providing a substantially homogeneous electric field across the electro-optic material 1220, thereby providing a substantially linear index gradient. Referring to FIG. 14, one implementation of an electro-optic prism 1400 configured to eliminate lensing is shown. In this implementation, an electrode 1410 provided on a face of the electro-optic material 1450 is patterned instead of contiguous. In this implementation, the patterned electrode 1410 is provided on the entrance face, although in another implementation the patterned electrode can be provided in the exit face.

The electrode 1410 can be patterned in linear strips 1435, where each strip can be individually wired with electrical connections that allow a unique voltage to be applied to each individual electrode, as depicted by V₁, V₂, V₃ . . . V_{N} in FIG. 14. The electric field in the vicinity of an electrode strip 1435 can thereby be controlled to account for the thickness of the electro-optic material 1450 adjacent to the electrode strip. Accordingly, increased voltages can be applied to the electrode strips 1435 at the thicker end 1430 of the electro-optic material 1450 and a reduced voltage applied toward the thinner end 1440. The additive effect of the individual voltages can provide a substantially homogeneous electric field, thereby causing the same amount of molecular rotation across the electro-optic material 1450 and hence a substantially linear index gradient. The effects of lensing can thereby be substantially eliminated.

In another implementation of an electro-optic prism 1500 shown in FIG. 15, one or more variable resistance electrodes 1570 can be used instead of a patterned electrode, e.g., 1410 in FIG. 14. In this implementation, one end 1520 of the variable resistance electrode 1570 can be held at a maximum required voltage V₂ and the other end 1530 can be held at a minimum required voltage V₁, which in one implementation is electrical ground. As current flows between the high potential 1520 and low potential 1530 ends of the resistance electrode 1570, the variable resistance of the resistance electrode 1570 dictates the local potential, and hence the local electric potential applied across the electro-optic material 1540. Again, by varying the electric potential applied to the differing thicknesses of the electro-optic layer 1540, a substantially homogeneous electric field can be applied resulting in a substantially linear index gradient.

In one implementation, the variable resistance electrode 1510 is fabricated by providing a layer of a transparent conductor with variable thickness. In another implementation, the variable resistance electrode 1510 is formed from a substantially uniformly thick, high-resistance transparent conductive layer that is patterned in such a manner as to effectively alter the resistance from one end 1520 to the other end 1530.

In one alternative implementation, the variable resistance electrode can be positioned on an inner surface of a top cover plate that shields the electro-optic material 1540 from the environment. A space between the cover plate and the entrance face of the electro-optic layer 1540 can include air and does not affect the deflection angle of impinging light rays.

### Varying Apex Angle

A prism having a triangular cross-section bends light rays through a given refraction angle that is primarily dependent upon the wavelength of the incident light, the index of refraction of the prism material, the apex angle of the prism, and the angle of incidence of the incoming rays. The apex angle is the angle subtended by the entrance and exit faces of the prism. As already discussed above, varying the refractive index of the prism material can provide a dynamic light steering effect. In another implementation, the apex angle can be varied to provide a dynamic light steering effect. Light rays can thereby be refracted dynamically without physically altering the prism's orientation.

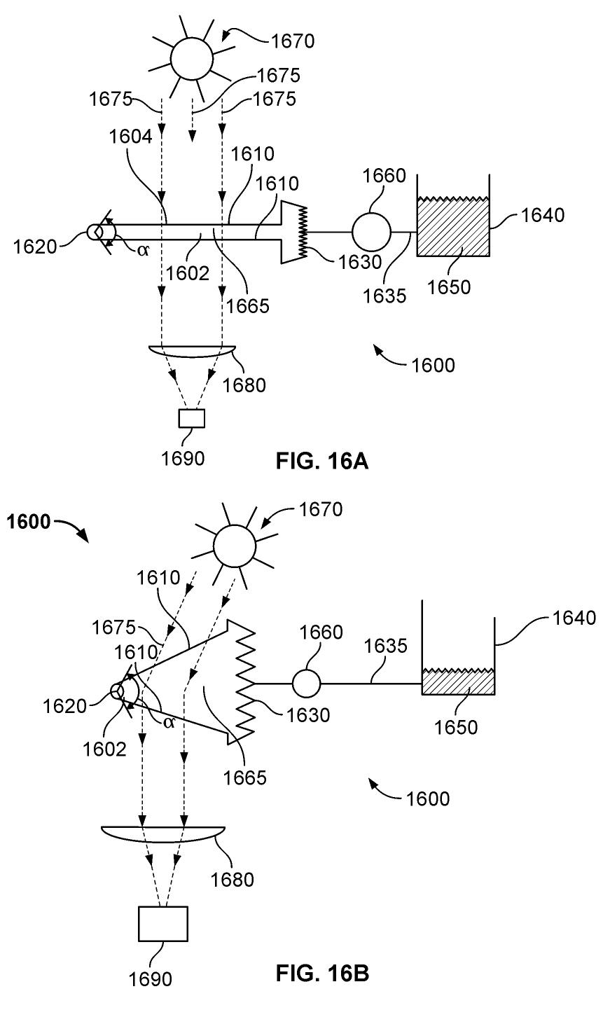

Referring to FIGS. 16A and 16B, one implementation of a prism assembly 1600 having a variable apex angle α is shown. In general, the prism 1600 has a variable volume and the apex angle α varies based on variations in the volume. In this implementation, the prism 1600 can include two transparent plates 1610 pivotally connected at the apex 1602. The plates 1610 can be connected by a pivotal connector 1620, including by way of example, a hinge or a living hinge. The orientation of the plates 1610 can be nearly vertical, nearly horizontal, or at any intermediate angle α. A third surface 1630 is connected to both plates 1610, forming a substantially triangular cross-section to the prism cavity 1665. The third surface 1630 is configured to expand and contract as the volume of the prism cavity 1665 varies. In one implementation, the third surface 1630 is an accordion-like configuration, as shown. In another implementation, the third surface 1630 is a flexible membrane.

The prism cavity 1665 is sealed on either end providing a liquid-tight container. The prism cavity 1665 is in fluid communication with a fluid source 1640, wherein varying the volume of fluid 1650 contained in the prism cavity 1665 varies the volume of the prism cavity 1665 and in turn varies the apex angle α. In one implementation, the fluid source is a reservoir 1640 containing a fluid 1650 connected by a hose 1635 to the prism cavity 1665. A pump 1660 can be used to precisely transfer fluid 1650 into and out of the prism cavity 1665.

When the light source 1670 is positioned such that the light rays 1675 impinge on the entrance surface 1604 of the prism 1600 at substantially a 90° angle, the prism cavity 1665 can be substantially drained of the fluid 1650, as shown in FIG. 16A. As the light source 1670 moves (e.g., the sun moving across the sky) the fluid 1650 can be pumped into the prism cavity 1665 to expand the volume and thereby increase the apex angle α, as shown in FIG. 16B. The increase in apex angle α is controlled to provide a controlled dynamic light-steering effect, such that the angle of the light rays 1675 exiting the prism 1600 is controlled. Examples of the fluid 1650 used in this implementation can include any low-viscosity, non-volatile liquid with low optical absorption. Fluids 1650 can be any of the materials generally referred to as “index matching fluids” known in the art and commonly used in optical microscopy applications.

In one implementation, the light rays exiting the prism 1600 can be substantially orthogonal relative to a receiving surface of a light focusing element 1680 positioned to focus light rays on a photovoltaic cell 1690. It may be beneficial to have two such prisms 1600 to provide full sky coverage from sunrise to sunset, as discussed previously.

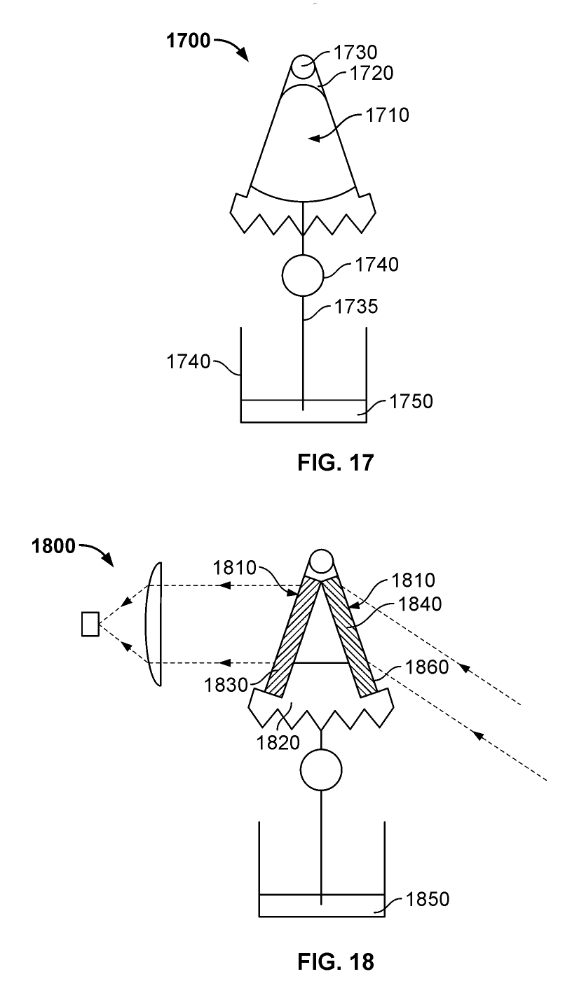

Referring to FIG. 17, another implementation of a variable apex-angle prism 1700 is shown. The prism 1700 has a similar configuration to the prism 1600 discussed above, however, in this implementation, a flexible, transparent bladder 1710 is included within the variable volume prism cavity 1720. The bladder 1710 allows fluid 1750 to be pumped (such as through hose 1735 and pump 1740 system) into and out of the prism cavity 1720 from a fluid source, such as a fluid reservoir 1740. The bladder can be made from any pliable, transparent plastic or polymer with suitable optical qualities, including low absorption and dispersion.

### Combined Variable-Apex Angle and Variable-Refractive Index Prism

To achieve an increased angular range for light-steering, a variable-apex angle design can be combined with a variable-refractive index design. Referring to FIG. 18, in this implementation of a dynamic prism 1800, fluid 1850 pumped into and out of the variable volume prism cavity 1820 is a liquid crystal material. The prism plates 1810 support electrodes 1830, 1840, such that an electric field can be applied to the liquid crystal 1850. In one implementation, one of the electrodes 1830 or 1840 is a variable resistance electrode, as discussed above, to eliminate a lensing effect. One or both of electrodes 1830 and 1840 may be linear parallel electrode strips, and can have individually-controllable voltages applied thereto, as described for electro-optic prism 202 in FIG. 2A. The electric field strength can be varied to vary the refractive index in combination with the apex angle being varied with the variable volume of the prism cavity 1820, providing controlled light steering of light rays impinging on the entrance face 1860.

### Radiation Filtering

In any of the above described implementations, the assemblies can be exposed to significant amounts of solar radiation, particularly in the infrared portion of the electromagnetic spectrum. Exposure to infrared radiation can cause undesirable heating. To protect against the negative effects of infrared radiation, a filter for reflecting, absorbing or otherwise redirecting infrared radiation, while allowing visible radiation to pass through for the purpose of reaching a photovoltaic device, can be employed. The filter can include, by way of example, one or more of a dichroic mirror, an interference filter, a cut-off filter and a diffraction grating. The filter can be used in conjunction with the various assemblies described herein, including the dynamic variable-power electro-optic prism, dynamic fixed-power electro-optic prism and static fixed-power electro-optic prism assemblies described.

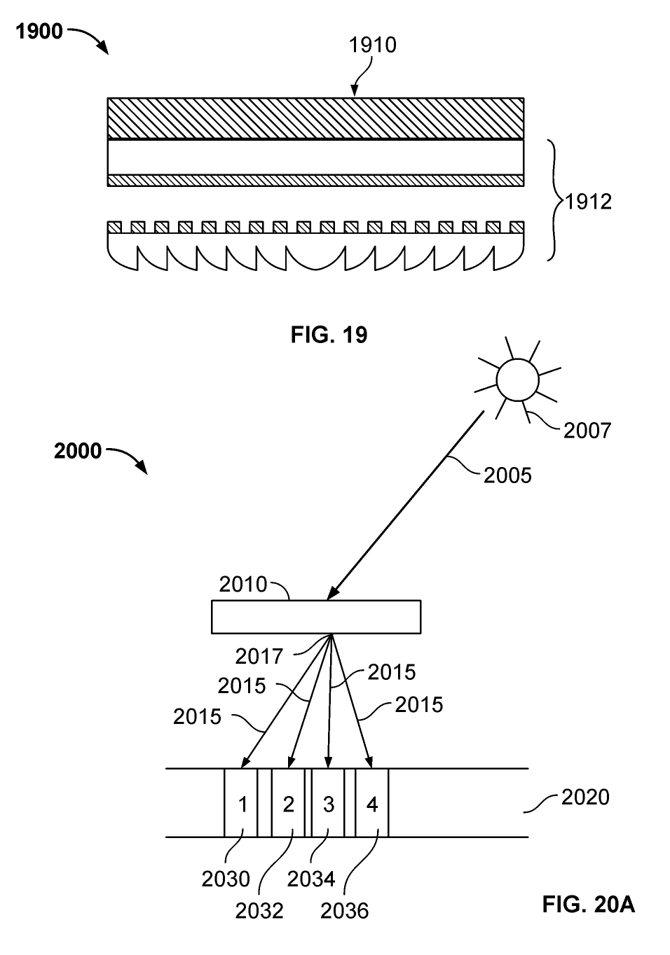

Referring to FIG. 19, a cross-sectional view of a schematic representation of a prism/light focusing element assembly 1900 including an infrared filter 1910 is shown. In this implementation, the infrared filter 1910 is positioned directly above and in optical communication with a dynamic electro-optic prism (e.g., any of the electro-optic prisms discussed above) 1912. Other configurations of prism/light focusing element assemblies can be used incorporating an infrared filter, and the configuration shown is but one example. Moreover, in other implementations a filter can be configured to reduce the effects of other types of radiation other than or in addition to infrared radiation. For example, in an outer-space application, it may be desirable to reduce exposure of a light directing system to other types of potentially damaging radiation or particles.

### Dispersive Properties of Prisms

Sunlight is a broadband illumination source. The refraction angle of the dynamic variable-power electro-optic prism can be optimized to steer light with a wavelength at the peak of the solar visible spectrum to the normal direction with respect to a receiving surface of a light focusing element.

All prisms exhibit dispersion. In one implementation, the dispersion can be maximized and two or more locations in a photovoltaic cell with different absorption properties can be targeted, such that an appropriate wavelength of light impinges on a corresponding location in the photovoltaic cell, thereby improving absorption and conversion efficiency over that of a single targeted location. Photovoltaic materials that absorb different regions of the solar spectrum are well known in the art. The solar spectrum is not homogeneous; there are some wavelengths that arrive at terrestrial levels in higher flux than others. In some implementations, it is desirable to use photovoltaic materials that are more sensitive at those wavelengths, thereby more efficiently converting light into electrical energy for those particular regions of the solar spectrum.

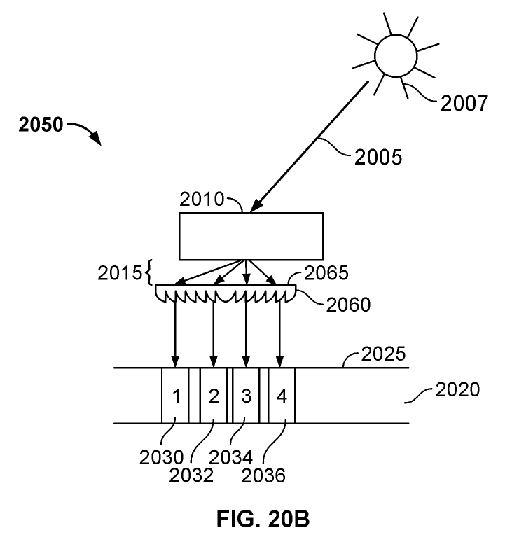

Referring to FIG. 20A, one implementation of a system 2000 where the dispersive properties of a prism is shown. In this implementation, the system 2000 includes an electro-optic prism (e.g., 202 in FIG. 2A) 2010 that refracts light from a broadband source, such as the sun 2007. The dispersive property of the prism 2010 can separate the broadband light into discrete wavelength “bands,” indicated by 2015, a prismatic effect which is well known. For example, a white-light beam entering a triangular prism separates the white light into a “rainbow” of colors as it exits the prism. A photovoltaic element 2020 includes different light-absorbing materials within one or more discrete cells 2030, 2032, 2034, 2036, which absorb wavelengths of light in a given range.

The electro-optic prism 2010 can steer incoming light rays 2005 such that when the light rays 2005 are subsequently divided into their constituent wavelength components 2015 by the prism 2010, the wavelength components 2015 are directed (by way of the light-steering property of the electro-optic prism 2010) to certain cells 2030, 2032, 2034, 2036. For example, cell #1 (2030) may be a photovoltaic material that is efficient at absorbing light in the wavelength range 1000-1600 nanometers (nm), but not wavelengths outside of this range. The electro-optic prism 2010 can be operated such that the dispersion and light-steering of the electro-optic prism 2010 directs wavelengths between 1000 nm and 1600 nm substantially toward cell #1 (2030). Other wavelength bands can be similarly substantially focused on the remaining cells according to the absorption properties of the cells, i.e., cells 2032, 2034, and 2036.

Referring to FIG. 20B, another implementation is shown including a light focusing element 2060 that directs the dispersed light onto the photovoltaic element 2020 at an angle substantially normal to the receiving surface 2025 of the photovoltaic 2020, which includes the aforementioned photovoltaic cells 2030, 2032, 2034, 2036. The light focusing element 2060 can reduce the effect to of spectral ‘bleeding’ into adjacent cells. For example, referring to FIG. 20A, dispersed rays exit the prism 2010 as substantially a point source 2017. If the distance from the prism 2010 to the photovoltaic element 2020 is not such that component wavelengths are spatially separated, then cells 2030 and 2032 can receive photons outside of their design purpose. The light focusing element 2060 included in the assembly in FIG. 20B can allows each dispersed spectral component to be directed substantially normal to the receiving surface of the photovoltaic element 2020, and also to the respective cell for which absorption will be maximized.

### Ultra-Violet to Visible Photon Conversion

The efficiency of a solar energy collection assembly can be improved by capturing radiation that falls outside the visible spectral region. For example, ultra-violet photons included in incoming solar radiation is down-converted into the visible band. In one implementation, certain chemical phosphors are included in the fluid of a light-steering mechanism, whether an electro-optic prism, a variable-apex prism or a combination thereof. In another implementation, an additional layer including chemical phosphors that optically communicates with the light-steering mechanism, and/or light focusing element is included. Ultra-violet light is thereby absorbed and converted into visible photons, steered normal onto a light focusing element, and concentrated onto a photovoltaic material, increasing the solar energy collection assembly's efficiency.

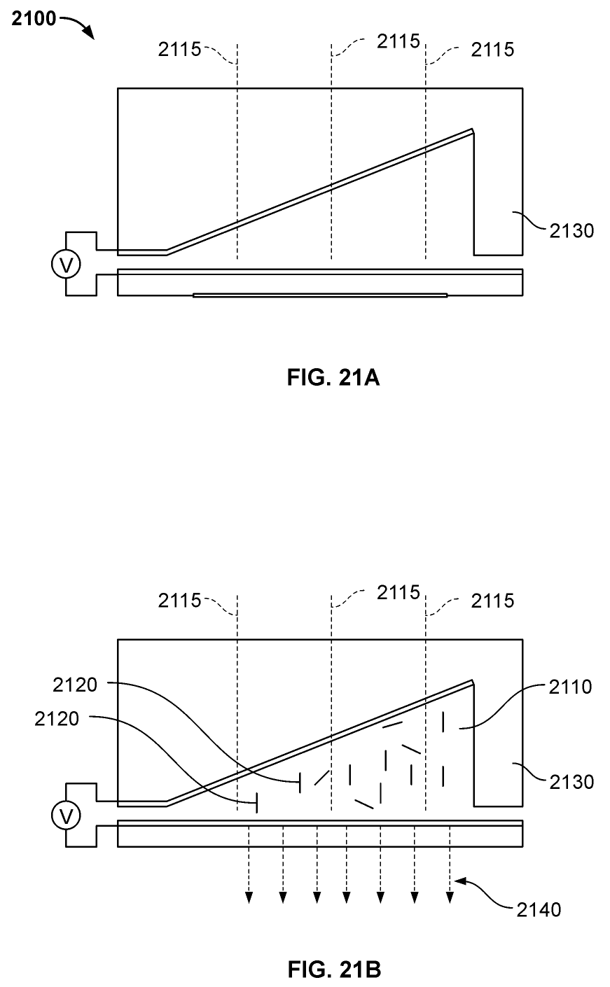

Referring to FIGS. 21A and 21B, one implementation of a light-steering mechanism employing ultra-violet light conversion is shown. In this example, the light-steering mechanism 2100 is a dynamic electro-optic prism 2130 as described above in reference to FIG. 13. FIG. 21A shows the prism 2130 without the inclusion of chemical phosphors to provide ultra-violet light conversion. As illustrated, ultraviolet photons 2115 incident on the prism 2130 are absorbed by some component of the prism 2130. This can arise from the absorption properties of the liquid crystal, the optical elements, or the electrodes, for example.

Referring now to FIG. 21B, the electro-optic prism 2130 includes chemical phosphors 2120 that can absorb the ultra-violet photons 2115 and emit a different frequency photon, generally characterized by the Stokes shift of the molecules 2120. The down-converted photons 2140 emitted from the electro-optic prism 2130 can be directed toward a photovoltaic cell via a light focusing element (not shown in FIG. 21B), where the photons 2140 are in a frequency range to be absorbable by a photovoltaic cell (not shown in FIG. 21B). In general, the phosphors used in this implementation can include, but are not limited to: organic dyes, inorganic phosphors, semi-conductor phosphors and quantum confined semi-conductors, such as nano-crystals, core-shell nano-crystals (an inorganic nano-crystal core surround by a shell of different semi-conductor), nanotubes, etc. By way of example only, the commercial laser dye Rhodamine 590 Chloride can be fluorescent (absorbs UV photons and emits visible photons) when dissolved in a liquid medium and could be added to the electro-active material used in an electro-active prism or the liquid used in a variable apex prism.

The technique of photon conversion described above can be implemented in the various light-steering mechanisms described herein, including without limitation the dynamic variable-power electro-optic prism, dynamic fixed-power electro-optic prism and static fixed-power electro-optic prism assemblies described.

### Stirling Engine Application

Stirling engines have been used in conjunction with solar collectors to drive generators to produce electricity. Solar heating is used to drive the Stirling engine at relatively high efficiency, which then rotates a generator armature to produce electric power. In one implementation, one or more electro-optic prisms in any configuration discussed herein for the purpose of light steering can be used to direct sunlight to a solar-powered Stirling engine, which can eliminate the necessity for a mechanical steering system for directing solar energy to the engine.

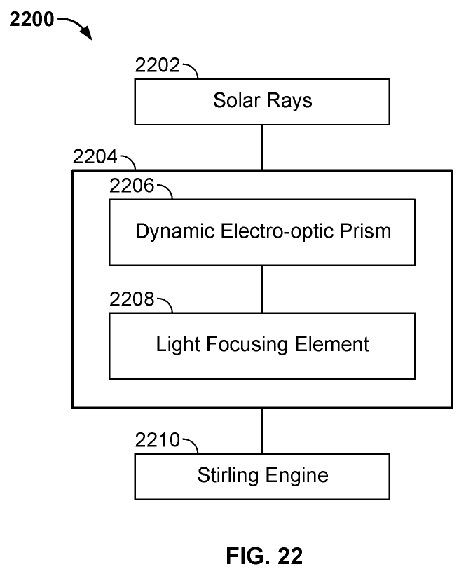

Referring to FIG. 22, a schematic representation of a system 2200 including a solar-powered Stirling engine 2210 is shown. The system 2200 includes a solar energy collection assembly 2204 configured to provide solar energy to the Stirling engine 2210. The solar energy collection assembly 2204 receives solar rays 2202 from the sun. The solar rays 2202 impinge on a dynamic electro-optic prism 2206, which can be configured in accordance with the various implementations described herein. The solar rays exit the dynamic electro-optic prism 2206 substantially normal to a receiving surface of a light focusing element 2208. The light focusing element 2208 focuses the solar rays 2202 toward a heating element of the Sterling engine 2210. Electrical power generated from the solar energy absorbed by the heating element powers the Stirling engine. In another implementation, a large-area array of dynamic electro-optic prisms individually steer light directly onto the absorber of the Stirling engine, which can eliminate the need for solar light ray focusing elements.

A number of implementations of the invention have been described. Nevertheless, it will be understood that various modifications can be made without departing from the spirit and scope of the invention. The devices enabled can be placed on crafts that exit the Earth's atmosphere, such as the Space Shuttle, or Space Station. The active absorbing medium can include semiconductors, as are known in the art, or other variants, to include nano-crystals, nano-tubes, and the like. Accordingly, other implementations are within the scope of the following claims.

What is claimed is:

1. An assembly comprising:
(a) an electro-optic prism configured to provide controllable steering of solar rays, wherein the electro-optic prism comprises
(i) a first electrode comprising a plurality of substantially parallel linear electrodes positioned on a first substrate,
(ii) a reference electrode positioned on a second substrate, and
(iii) an electro-optic material positioned between the first electrode and the reference electrode such that, when separately controllable voltages are provided to at least some of the linear electrodes, a gradient electric field is provided within the electro-optic material to cause the electro-optic material to have a refractive index gradient and wherein the refractive index gradient can be controlled by varying the magnitude of the separately controllable voltages provided to at least some of the linear electrodes; and
(b) a wavelength selective filter in optical communication with the electro-optic prism, wherein the wavelength selective filter is configured to substantially eliminate selected wavelengths from solar rays before the solar rays are received by the electro-optic prism.

2. The assembly of claim 1, wherein the wavelength selective filter is one that substantially blocks infrared radiation.

3. The assembly of claim 2, wherein infrared radiation comprises wavelengths greater than approximately 1800 nanometers.

4. The assembly of claim 1, wherein the wavelength selective filter comprises a dichroic mirror.

5. The assembly of claim 1, wherein the wavelength selective filter comprises an interference filter.

6. The assembly of claim 1, wherein the wavelength selective filter comprises a diffraction grating.

7. The assembly of claim 1, wherein the wavelength selective filter comprises a cut-off filter.

8. The assembly of claim 1, further comprising a light focusing element, wherein the light focusing element is arranged in optical communication with the dynamic variable-power electro-optic prism and positioned to receive and concentrate the solar rays after having passed through the dynamic variable-power electro-optic prism.

9. The assembly of claim 8, further comprising a photovoltaic device in optical communication with the light focusing element, wherein the light focusing element concentrates the light rays toward the photovoltaic device.

10. An assembly comprising:
(a) an electro-optic prism configured to provide controllable steering of solar rays, wherein the electro-optic prism comprises
(i) a first electrode comprising a plurality of substantially parallel linear electrodes positioned on a first substrate,
(ii) a reference electrode positioned on a second substrate, and
(iii) an electro-optic material positioned between the first electrode and the reference electrode such that, when separately controllable voltages are provided to at least some of the linear electrodes, a gradient electric field is provided within the electro-optic material to cause the electro-optic material to have a refractive index gradient and wherein the refractive index gradient can be controlled by varying the magnitude of the separately controllable voltages provided to at least some of the linear electrodes; and
(b) a chemical compound configured in the assembly to convert ultra-violet photons included in the solar rays into visible photons.

11. The assembly of claim 10, wherein the chemical compound is included within the electro-optic material of the electro-optic prism.

12. The assembly of claim 10, wherein the chemical compound comprises a material in optical communication with the electro-optic prism.

13. The assembly of claim 10, wherein the chemical compound is an organic dye compound.

14. The assembly of claim 10, wherein the chemical compound is an inorganic phosphor.

15. The assembly of claim 14, wherein the inorganic phosphor is a semiconductor material.

16. The assembly of claim 15, wherein the semiconductor material exhibits quantum confinement.

17. The assembly of claim 10, further comprising a light focusing element, wherein the light focusing element is arranged in optical communication with the electro-optic prism and positioned to receive and concentrate the solar rays after having passed through the electro-optic prism.

18. The assembly of claim 10, further comprising a photovoltaic device in optical communication with the light focusing element, wherein the light focusing element concentrates the light rays toward the photovoltaic device.

19. A assembly comprising:
(a) an electro-optic prism configured to provide controllable steering of solar rays, wherein the electro-optic prism comprises
(i) a first electrode comprising a plurality of substantially parallel linear electrodes positioned on a first substrate,
(ii) a reference electrode positioned on a second substrate, and
(iii) an electro-optic material positioned between the first electrode and the reference electrode; and
(b) a wavelength selective filter in optical communication with the electro-optic prism, wherein the wavelength selective filter is configured to substantially eliminate selected wavelengths from solar rays before the solar rays are received by the electro-optic prism.

20. An assembly comprising:
(a) an electro-optic prism configured to provide controllable steering of solar rays, wherein the electro-optic prism comprises
(i) first electrode comprising a plurality of substantially parallel linear electrodes positioned on a first substrate,
(ii) a reference electrode positioned on a second substrate, and
(iii) an electro-optic material positioned between the first electrode and the reference electrode; and
(b) a chemical compound configured in the assembly to convert ultra-violet photons included in the solar rays into visible photons.
